(19) United States
(12) Patent Application Publication
(10) Pub. No.: US 2009/0072880 A1
(43) Pub. Date: Mar. 19, 2009

(54) OUTPUT CIRCUIT, OUTPUT CIRCUIT GROUP, AND SEMICONDUCTOR INTEGRATED CIRCUIT INCLUDING THE SAME

(75) Inventor: Shinichiro KOBAYASHI, Hino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/171,959

(22) Filed: Jul. 11, 2008

(30) Foreign Application Priority Data
Sep. 18, 2007 (JP) 2007-240672

(51) Int. Cl. H03L 5/00

(52) U.S. Cl. 327/333

(57) ABSTRACT

An output circuit group comprises at least one first output circuit that outputs a pair of differential signals, the first output circuit including a first reversing circuit operated by applying a first power supply potential and a second power supply potential to reverse a first driving signal so as to output a first reverse driving signal, a first signal level converting circuit operated by applying the first power supply potential and a third power supply potential to convert the first driving signal to a signal having a predetermined level to output, a second signal level converting circuit operated by applying the first and the third power supply potentials to convert the first reverse driving signal to a signal having a predetermined level to output, a first differential circuit operated by applying the first and the third power supply potentials to output a signal having a first polarity corresponding to a difference between the signal output from the first signal level converting circuit and the signal output from the second signal level converting circuit, a second differential circuit operated by applying the first and the third power supply potentials to output a signal having a second polarity that is opposite to the first polarity and corresponding to a difference between the signal output from the second signal level converting circuit and the signal output from the first signal level converting circuit, a first output signal generating circuit operated by applying the first and the third power supply potentials to generate a first output signal based on the signal having the first polarity output from the first differential circuit, and a second output signal generating circuit operated by applying the first and the third power supply potentials to generate a second output signal based on the signal having the second polarity output from the second differential circuit, the first and the second output signals being included in the differential signals; and at least one second output circuit that outputs a single forward or reverse signal, the second output circuit including a second reversing circuit operated by applying the first and the second power supply potentials to reverse a second driving signal so as to output a second reverse driving signal, a third signal level converting circuit operated by applying the first and the third power supply potentials to convert the second driving signal to a signal having a predetermined level to output, a fourth signal level converting circuit operated by applying the first and the third power supply potentials to convert the second reverse driving signal to a signal having a predetermined level to output, a third differential circuit operated by applying the first and the third power supply potentials to output a signal having a first polarity corresponding to a difference between the signal output from the third signal level converting circuit and the signal output from the fourth signal level converting circuit, a loading circuit connected to an output terminal of each of the third and the fourth signal level converting circuits to have a load capacitance approximately equal to a load capacitance of the third differential circuit, and a third output signal generating circuit operated by applying the first and the third power supply potentials to generate the forward or reverse signal based on the signal having the first polarity output from the third differential circuit.

The entire disclosure of Japanese Patent Application No. 2007-240672, filed Sep. 18, 2007 is expressly incorporated by reference herein.

### BACKGROUND

1. Technical Field

Several aspects of the present invention relates to an output circuit outputting a signal to an external circuit and to an output circuit group. The invention also relates to a semiconductor integrated circuit including the output circuit group.

2. Related Art

Recently, transmission speed of interface signals has become much faster, where there is a need to control noise and electromagnetic interference (EMI) in the signals. In control of the noise and EMI in the interface signals, signal amplitudes are reduced. However, reducing the signal amplitudes by lowering a power supply voltage supplied to an output circuit leads to complexity of a power supply circuit. Additionally, there can occur a difference in a reference level of signal strength between a high power supply potential circuit and a low power supply potential circuit.

Furthermore, differential signals are often used as such interface signals. It is significantly necessary for a differential signal output circuit to reduce skews occurring between signals included in the differential signals. In order to reduce the skews, a capacitor is used (e.g. see FIG. 19 in Japanese Patent No. 3852447). However, in the differential signal output circuit, production process variations tend to cause a difference between a capacitance required to reduce the skews and an actually formed capacitance. This can lead to yield reduction or can cause product defects on customer sites. Additionally, it is necessary to provide strict safety margins against power supply potential fluctuations, temperature fluctuations, and the like, which can result in yield reduction.

Given the above problems, the inventor of the present invention has proposed an output circuit and the like that can reduce the skews to prevent yield reduction and the like (see the Japanese Patent cited above).

Meanwhile, actually, various semiconductor integrated circuits and electronic apparatuses often use differential signals mixed with a single forward or reverse signal. Then, in known output circuits outputting such a forward or reverse signal, a delay amount of the forward or reverse signal is different in each operational condition. Thus, although the output circuit of the above Japanese patent by the inventor of the present invention reduces the skews between the signals included in the differential signals, there can occur a phase deviation between the differential signals and the forward or reverse signal. Thus, it is extremely difficult to adjust timings of changes in signals.

### SUMMARY

Therefore, the present invention has been accomplished in light of the above technical problems. An advantage of the present invention is to provide an output circuit group that makes it easy or unnecessary to adjust timings of changes in differential signals and a single forward or reverse signal. Another advantage of the invention is to provide an output circuit outputting the forward or reverse signal to achieve the above feature. Another advantage of the invention is to provide a semiconductor integrated circuit including the output circuit group.

An output circuit group according to a first aspect of the invention includes at least one first output circuit that outputs a pair of differential signals, the first output circuit including a first reversing circuit operated by applying a first power supply potential and a second power supply potential to reverse a first driving signal so as to output a first reverse driving signal, a first signal level converting circuit operated by applying the first power supply potential and a third power supply potential to convert the first driving signal to a signal having a predetermined level to output, a second signal level converting circuit operated by applying the first and the third power supply potentials to convert the first reverse driving signal to a signal having a predetermined level to output, a first differential circuit operated by applying the first power supply potential and a fourth power supply potential to output a signal having a first polarity corresponding to a difference between the signal output from the first signal level converting circuit and the signal output from the second signal level converting circuit, a second differential circuit operated by applying the first and the fourth power supply potentials to output a signal having a second polarity that is opposite to the first polarity and corresponding to a difference between the signal output from the second signal level converting circuit and the signal output from the first signal level converting circuit, a first output signal generating circuit operated by applying the first and the fourth power supply potentials to generate a first output signal based on the signal having the first polarity output from the first differential circuit, and a second output signal generating circuit operated by applying the first and the fourth power supply potentials to generate a second output signal based on the signal having the second polarity output from the second differential circuit, the first and the second output signals being included in the differential signals; and at least one second output circuit that outputs a single forward or reverse signal, the second output circuit including a second reversing circuit operated by applying the first and the second power supply potentials to reverse a second driving signal so as to output a second reverse driving signal, a third signal level converting circuit operated by applying the first and the third power supply potentials to convert the second driving signal to a signal having a predetermined level to output, a fourth signal level converting circuit operated by applying the first and the third power supply potentials to convert the second reverse driving signal to a signal having a predetermined level to output, a third differential circuit operated by applying the first and the fourth power supply potentials to output a signal having a first polarity corresponding to a difference between the signal output from the third signal level converting circuit and the signal output from the fourth signal level converting circuit, a loading circuit connected to an output terminal of each of the third and the fourth signal level converting circuits to have a load capacitance approximately equal to a load capacitance of the third differential circuit, and a third output signal generating circuit operated by applying the first and the fourth power supply potentials to generate the forward or reverse signal based on the signal having the first polarity output from the third differential circuit.

In the output circuit group according to the first aspect, a phase difference between the first and the second driving signals can be made approximately equal to a phase difference between the differential signals output from the first output circuit and the forward or reverse signal output from the second output circuit. This makes it easy or unnecessary to adjust the timings of changes in the differential signals and the forward or reverse signal.

An output circuit group according to a second aspect of the invention includes at least one first output circuit that outputs a pair of differential signals, the first output circuit including a first reversing circuit operated by applying a first power supply potential and a second power supply potential to reverse a first driving signal so as to output a first reverse driving signal, a first signal level converting circuit operated by applying the first power supply potential and a third power supply potential to convert the first driving signal to a signal having a predetermined level to output, a second signal level converting circuit operated by applying the first and the third power supply potentials to convert the first reverse driving signal to a signal having a predetermined level to output, a first differential circuit operated by applying the first power supply potential and a fourth power supply potential to output a signal having a first polarity corresponding to a difference between the signal output from the first signal level converting circuit and the signal output from the second signal level converting circuit, a second differential circuit operated by applying the first and the fourth power supply potentials to output a signal having a second polarity that is opposite to the first polarity and corresponding to a difference between the signal output from the second signal level converting circuit and the signal output from the first signal level converting circuit, a first output signal generating circuit operated by applying the first and the fourth power supply potentials to generate a first output signal based on the signal having the first polarity output from the first differential circuit, and a second output signal generating circuit operated by applying the first and the fourth power supply potentials to generate a second output signal based on the signal having the second polarity output from the second differential circuit, the first and the second output signals being included in the differential signals; and at least one second output circuit that outputs a single forward or reverse signal, the second output circuit including a second reversing circuit operated by applying the first and the second power supply potentials to reverse a second driving signal so as to output a second reverse driving signal, a third signal level converting circuit operated by applying the first and the third power supply potentials to convert the second driving signal to a signal having a predetermined level to output, a fourth signal level converting circuit operated by applying the first and the third power supply potentials to convert the second reverse driving signal to a signal having a predetermined level to output, a third differential circuit operated by applying the first and the fourth power supply potentials to output a signal having a first polarity corresponding to a difference between the signal output from the third signal level converting circuit and the signal output from the fourth signal level converting circuit, a loading circuit connected to an output terminal of each of the third and the fourth signal level converting circuits to have a load capacitance approximately equal to a load capacitance of the third differential circuit, and a third output signal generating circuit operated by applying the first and the fourth power supply potentials to generate the forward or reverse signal based on the signal having the first polarity output from the third differential circuit.

In the output circuit group according to the second aspect, the phase difference between the first and the second driving signals can be made approximately equal to the phase difference between the differential signals output from the first output circuit and the forward or reverse signal output from the second output circuit. This makes it easy or unnecessary to adjust the timings of changes in the differential signals and the forward or reverse signal.

Preferably, in the output circuit group according to the second aspect, the third power supply potential is higher than the second power supply potential, and the fourth power supply potential is higher than the third power supply potential.

In this manner, the first output circuit also serves as a step-up circuit.

Preferably, in the output circuit group according to the second aspect, the third power supply potential is lower than the second power supply potential, and the fourth power supply potential is lower than the third power supply potential.

In this manner, the first output circuit also serves as a step-down circuit.

Preferably, in the output circuit group according to the first aspect, a phase difference between the first and the second driving signals is approximately equal to a phase difference between the differential signals output from the first output circuit and the forward or reverse signal output from the second output circuit.

This makes it easy or unnecessary to adjust the timings of changes in the differential signals and the forward or reverse signal.

Preferably, in the output circuit group according to the first aspect, the loading circuit is a dummy differential circuit having a structure approximately equal to a structure of the third differential circuit.

In this manner, a load balance between the third and the fourth signal level converting circuits can be easily maintained.

Preferably, in the output circuit group according to the first aspect, the loading circuit includes a first loading element having a load capacitance approximately equal to an input load capacitance of a first input terminal of the third differential circuit and a second loading element having a load capacitance approximately equal to an input load capacitance of a second input terminal of the third differential circuit.

In this manner, the load balance between the third and the fourth signal level converting circuits can be easily maintained by using a small number of elements.

A semiconductor integrated circuit according to a third aspect of the invention includes a chip having a plurality of circuit regions formed thereon, each region having separate power supplies, and the output circuit group according to the first aspect, the output circuit group being formed in one of the circuit regions.

In the semiconductor integrated circuit according to the third aspect, it is easy to provide a design guarantee against production process fluctuations, power supply potential fluctuations, and operational temperature fluctuations.

Preferably, in the semiconductor integrated circuit according to the third aspect, the one of the circuit regions having the output circuit group formed therein includes a plurality of power supply voltage regions formed in parallel in a side direction of the chip, and each of the first and the second output circuits included in the output circuit group is formed so as to straddle the power supply voltage regions.

This facilitates a layout on the chip.

An output circuit according to a fourth aspect of the invention is an output circuit that outputs a single forward or reverse signal based on a driving signal. The output circuit of the fourth aspect includes a reversing circuit operated by applying a first power supply potential and a second power supply potential to reverse the driving signal so as to output a reverse driving signal; a first signal level converting circuit operated by applying the first power supply potential and a third power supply potential to convert the driving signal to a signal having a predetermined level to output; a second signal level converting circuit by applying the first and the third power supply potentials to convert the reverse driving signal to a signal having a predetermined level to output; a differential circuit operated by applying the first and the third power supply potentials to output a signal having a predetermined polarity corresponding to a difference between the signal output from the first signal level converting circuit and the signal output from the second signal level converting circuit; a loading circuit connected to an output terminal of each of the first and the second signal level converting circuits to have a load capacitance approximately equal to a load capacitance of the differential circuit; and an output signal generating circuit operated by applying the first and the third power supply potentials to generate the forward or reverse signal based on the signal having the predetermined polarity output from the differential circuit.

The output circuit according to the fourth aspect makes it easy or unnecessary to adjust the timings of changes in the differential signals and the single forward or reverse signal.

An output circuit according to a fifth aspect of the invention is an output circuit that outputs a single forward or reverse signal based on a driving signal. The output circuit of the fifth aspect includes a reversing circuit operated by applying a first power supply potential and a second power supply potential to reverse the driving signal so as to output a reverse driving signal; a first signal level converting circuit operated by applying the first power supply potential and a third power supply potential to convert the driving signal to a signal having a predetermined level to output; a second signal level converting circuit operated by applying the first and the third power supply potentials to convert the reverse driving signal to a signal having a predetermined level to output; a differential circuit operated by applying the first power supply potential and a fourth power supply potential to output a signal having a predetermined polarity corresponding to a difference between the signal output from the first signal level converting circuit and the signal output from the second signal level converting circuit; a loading circuit connected to an output terminal of each of the first and the second signal level converting circuits to have a load capacitance approximately equal to a load capacitance of the differential circuit; and an output signal generating circuit operated by applying the first and the fourth power supply potentials to generate the forward or reverse signal based on the signal having the predetermined polarity output from the differential circuit.

The output circuit according to the fifth aspect makes it easy or unnecessary to adjust the timings of changes in the differential signals and the single forward or reverse signal.

Preferably, in the output circuit according to the fifth aspect, the loading circuit is a dummy differential circuit having a structure approximately equal to a structure of the differential circuit.

In this manner, the load balance between the third and the fourth signal level converting circuits can be easily maintained.

Preferably, in the output circuit according to the fifth aspect, the loading circuit includes a first loading element having a load capacitance approximately equal to an input load capacitance of a first input terminal of the differential circuit and a second loading element having a load capacitance approximately equal to an input load capacitance of a second input terminal of the differential circuit.

In this manner, the load balance between the third and the fourth signal level converting circuits can be easily maintained by using the small number of elements.

An output circuit group according to a sixth aspect of the invention includes at least one first output circuit that outputs a pair of differential signals, the first output circuit including a first reversing circuit that reverses a first driving signal to output a first reverse driving signal, a first signal level converting circuit that converts the first driving signal to a signal having a predetermined level to output, a second signal level converting circuit that converts the first reverse driving signal to a signal having a predetermined level to output, a first differential circuit that outputs a signal having a first polarity corresponding to a difference between the signal output from the first signal level converting circuit and the signal output from the second signal level converting circuit, a second differential circuit that outputs a signal having a second polarity opposite to the first polarity and corresponding to a difference between the signal output from the second signal level converting circuit and the signal output from the first signal level converting circuit, a first output signal generating circuit that generates a first output signal based on the signal having the first polarity output from the first differential circuit, and a second output signal generating circuit that generates a second output signal based on the signal having the second polarity output from the second differential circuit; and at least one second output circuit that outputs a single forward or reverse signal, the second output circuit including a second reversing circuit that reverses a second driving signal to output a second reverse driving signal, a third signal level converting circuit that converts the second driving signal to a signal having a predetermined level to output, a fourth signal level converting circuit that converts the second reverse driving signal to a signal having a predetermined level to output, a third differential circuit that outputs a signal having a first polarity corresponding to a difference between the signal output from the third signal level converting circuit and the signal output from the fourth signal level converting circuit, a loading circuit connected to an output terminal of each of the third and the fourth signal level converting circuits to have a load capacitance approximately equal to a load capacitance of the third differential circuit, and a third output signal generating circuit that generates the forward or reverse signal based on the signal having the first polarity output from the third differential circuit, wherein each of the first to the fourth signal level converting circuits includes a first MOS transistor of a first type whose gate receives the first driving signal, the first reverse driving signal, the second driving signal, or the second reverse driving signal and whose drain outputs a signal, a second MOS transistor of a second type whose gate receives a third driving signal and whose drain outputs a signal, and a negative feedback circuit that negatively feeds back a signal obtained by synthesizing the signals output from the drains of the first and the second MOS transistors to the gate of the second MOS transistor to generate the third driving signal so as to control an operating point of the second MOS transistor.

In the output circuit group according to the sixth aspect, providing the negative feedback by using the feedback circuit enables a high-speed operation by a simple circuit structure.

An output circuit group according to a seventh aspect of the invention includes at least one first output circuit that outputs a pair of differential signals, the first output circuit including a first reversing circuit that reverses a first driving signal to output a first reverse driving signal, a first signal level converting circuit that converts the first driving signal to a signal having a predetermined level to output, a second signal level converting circuit that converts the first reverse driving signal to a signal having a predetermined level to output, a first differential circuit that outputs a signal having a first polarity corresponding to a difference between the signal output from the first signal level converting circuit and the signal output from the second signal level converting circuit, a second differential circuit that outputs a signal having a second polarity opposite to the first polarity and corresponding to a difference between the signal output from the second signal level converting circuit and the signal output from the first signal level converting circuit, a first output signal generating circuit that generates a first output signal based on the signal having the first polarity output from the first differential circuit, and a second output signal generating circuit that generates a second output signal based on the signal having the second polarity output from the second differential circuit; and at least one second output circuit that outputs a single forward or reverse signal, the second output circuit including a second reversing circuit that reverses a second driving signal to output a second reverse driving signal, a third signal level converting circuit that converts the second driving signal to a signal having a predetermined level to output, a fourth signal level converting circuit that converts the second reverse driving signal to a signal having a predetermined level to output, a third differential circuit that outputs a signal having a first polarity corresponding to a difference between the signal output from the third signal level converting circuit and the signal output from the fourth signal level converting circuit, a loading circuit connected to an output terminal of each of the third and the fourth signal level converting circuits to have a load capacitance approximately equal to a load capacitance of the third differential circuit, and a third output signal generating circuit that generates the forward or reverse signal based on the signal having the first polarity output from the third differential circuit, wherein each of the first to the fourth signal level converting circuits includes a first MOS transistor whose gate receives the first driving signal, the first reverse driving signal, the second driving signal, or the second reverse driving signal and whose drain outputs a signal, a second MOS transistor whose gate receives a third driving signal and whose source outputs a signal, and a negative feedback circuit that reverses a signal obtained by synthesizing the signal output from the drain of the first MOS transistor and the signal output from the source of the second MOS transistor to negatively feeds back to the gate of the second MOS transistor to generate the third driving signal to control an operating point of the second MOS transistor.

In the output circuit group according to the seventh aspect, providing the negative feedback by using the feedback circuit enables a high-speed operation by a simple circuit structure.

Preferably, a phase difference between the first and the third driving signals is approximately equal to a phase difference between the differential signals output from the first output circuit and the forward or reverse signal output from the second output circuit.

This makes it easy or unnecessary to adjust the timings of changes in the differential signals and the forward or reverse signal.

Preferably, in the output circuit group according to the seventh aspect, the loading circuit is a dummy differential circuit having a structure approximately equal to a structure of the third differential circuit.

In this manner, the load balance between the third and the fourth signal level converting circuits can be easily maintained.

Preferably, in the output circuit group according to the seventh aspect, the loading circuit includes a first loading element having a load capacitance approximately equal to an input load capacitance of a first input terminal of the third differential circuit and a second loading element having a load capacitance approximately equal to an input load capacitance of a second input terminal of the third differential circuit.

In this manner, the load balance between the third and the fourth signal level converting circuits can be easily maintained by using the small number of elements.

A semiconductor integrated circuit according to an eighth aspect of the invention includes a chip having a plurality of circuit regions formed thereon, each region having separate power supplies, and the output circuit group according to the seventh aspect, the output circuit group being formed in one of the circuit regions.

In the semiconductor integrated circuit according to the eighth aspect, it is easy to provide the design guarantee against production process fluctuations, power supply potential fluctuations, and operational temperature fluctuations.

Preferably, in the semiconductor integrated circuit according to the eighth aspect, the one of the circuit regions having the output circuit group formed therein includes a plurality of power supply voltage regions formed in parallel in a side direction of the chip, and each of the first and the second output circuits included in the output circuit group is formed so as to straddle the power supply voltage regions.

In this manner, the layout on the chip can be easily provided.

### BRIEF DESCRIPTION OF THE DRAWINGS

The invention will be described with reference to the accompanying drawings, wherein like numbers reference like elements.

FIG. 1 is a schematic view of an output circuit group according to a first embodiment of the invention.

FIG. 2 is a diagram showing an example of an internal structure of a differential signal output circuit shown in FIG. 1.

FIG. 3 is a timing chart showing an operation of the differential signal output circuit shown in FIG. 2.

FIG. 4 is a diagram showing an example of an internal structure of a single signal output circuit shown in FIG. 1.

FIG. 5 is a timing chart showing an operation of the single signal output circuit shown in FIG. 4.

FIGS. 6A and 6B each are a schematic view of a semiconductor integrated circuit according to a second embodiment of the invention.

FIG. 7 is a diagram showing a layout example of I/O cells shown in FIGS. 6A and 6B.

FIG. 8 is a diagram showing an example of an internal structure of a single signal output circuit according to a third embodiment of the invention.

FIG. 9 is a diagram showing an example of an internal structure of a single signal output circuit according to a fourth embodiment of the invention.

FIG. 10 is a diagram showing an example of an internal structure of a single signal output circuit according to a fifth embodiment of the invention.

FIG. 11 is a diagram showing an example of an internal structure of a single signal output circuit according to a sixth embodiment of the invention.

FIG. 12 is a diagram showing an example of an internal structure of a single signal output circuit according to a seventh embodiment of the invention.

FIG. 13 is a diagram showing an example of an internal structure of a single signal output circuit according to an eighth embodiment of the invention.

FIG. 14 is a diagram showing an example of an internal structure of a single signal output circuit according to a ninth embodiment of the invention.

FIG. 15 is a schematic view of a semiconductor integrated circuit according to a tenth embodiment of the invention.

FIG. 16 is a diagram showing an example of an internal structure of a single signal output circuit according to an eleventh embodiment of the invention.

FIG. 17 is a diagram showing an example of an internal structure of a single signal output circuit according to a twelfth embodiment of the invention.

FIG. 18 is a diagram showing an example of an internal structure of a single signal output circuit according to a thirteenth embodiment of the invention.

### DESCRIPTION OF EXEMPLARY EMBODIMENTS

Hereinafter, embodiments of the invention will be described in detail. The embodiments described below do not unduly restrict the scope of the invention defined in the appended claims. Additionally, not all of features described in the embodiments are necessarily essential as solving means of the invention. The same constituent elements are given the same reference numerals throughout the drawings, and an overlapping description thereof will be omitted.

First will be described a first embodiment of the invention.

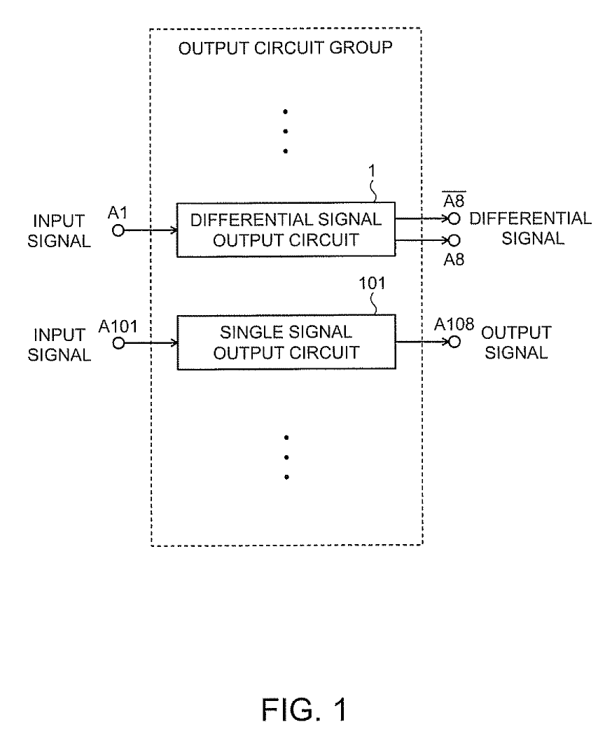

FIG. 1 is a diagram of a structural example of an output circuit group according to the first embodiment. The output circuit group includes at least one differential signal output circuit (generally, a first output circuit) 1 that outputs a pair of differential signals and at least one single signal output circuit (generally, a second output circuit) 101 that outputs a single forward or reverse signal.

FIG. 1 shows the differential signal output circuit 1. However, the output circuit group may include two or more differential signal output circuits. Additionally, FIG. 1 also shows the single signal output circuit 101. However, the output circuit group may include two or more single signal output circuits.

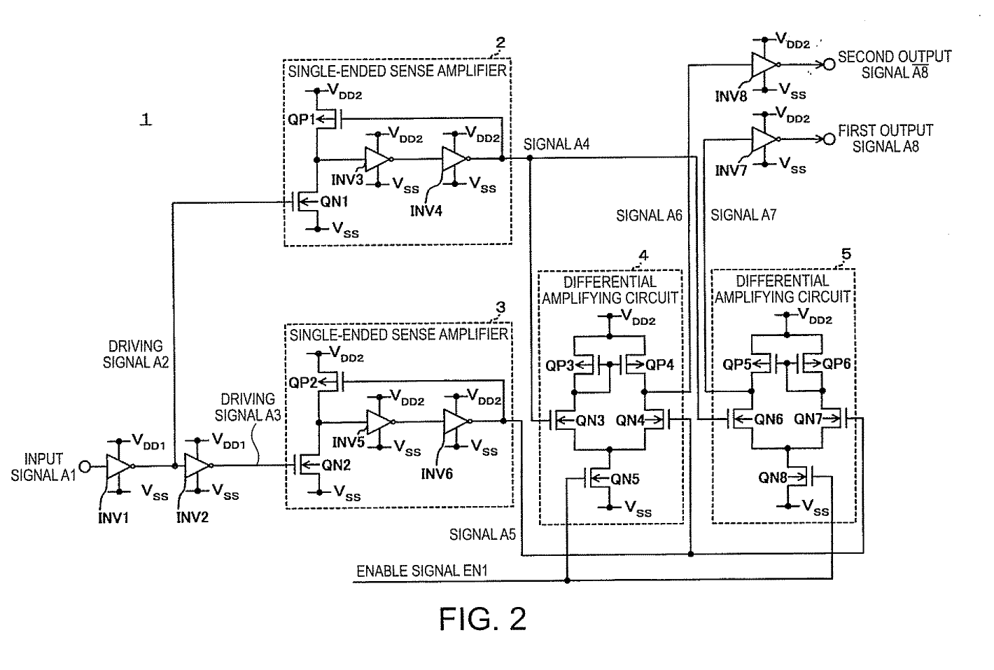

FIG. 2 is a diagram showing an example of an internal structure of the differential signal output circuit 1 shown in FIG. 1. The differential signal output circuit 1 outputs a first output signal A8 and a second output signal A8-bar as the pair of differential signals based on an input signal A1. Additionally, the differential signal output circuit 1 includes inverters INV1, INV2 (generally, inversion circuits), inverters INV7, INV8 (generally, output signal generating circuits), single-ended sense amplifiers 2, 3 (generally, signal level converting circuits), and current mirror differential amplifying circuits (generally, differential circuits) 4, 5. The inverters INV1 and INV2 are operated by applying a power supply potential V_{SS} at a low potential level (generally, a first power supply potential) and a power supply potential V_{DD1} at a high potential level (generally, a second power supply potential). The inverters INV7, INV8, the single-ended sense amplifiers 2, 3, and the current mirror differential amplifying circuits 4, 5 are operated by applying a power supply potential V_{DD2} at a high potential level (generally, a third power supply potential) and the low power supply potential V_{SS}.

As shown in FIG. 2, the input signal A1 is supplied to the inverter INV1, which in turn reverses the input signal A1 to output as a driving signal A2. In the present embodiment, the input signal A1 and the driving signal A2 change between the low potential V_{SS} and the high potential V_{DD1}.

The driving signal A2 is supplied to the inverter INV2, which in turn reverses the driving signal A2 to output as a driving signal A3. In the embodiment, the driving signal A3 changes between the low potential V_{SS} and the high potential V_{DD1}.

The single-ended sense amplifier 2 includes a P-channel transistor QP1, an N-channel transistor QN1, and inverters INV3, INV4. The single-ended sense amplifier 2 reverses the driving signal 2 and then converts a level of the reverse signal to a predetermined level to output as a signal A4 to the differential amplifying circuits 4 and 5.

In the single-ended sense amplifier 2, source-to-drain paths of the transistors QP1 and QN1 are connected in series between the high power supply potential V_{DD2} and the low power supply potential V_{SS}. The driving signal A2 is supplied to a gate of the transistor QN1. A junction between the transistors QP1 and QN1 is connected to an input terminal of the inverter INV3. An output signal of the inverter INV3 is supplied to the inverter INV4.

An output terminal of the inverter INV4 is connected to a gate of the transistor QP1. The transistor QP1 constitutes a negative feedback loop from the output terminal of the inverter INV4 to the input terminal of the inverter INV3. Accordingly, a level of the signal A4 output from the inverter INV4 corresponds to a gain of the above negative feedback loop. The signal A4 output from the inverter INV4 is fed back to the gate of the transistor QP1 and also supplied to the differential amplifying circuits 4 and 5.

Additionally, the single-ended sense amplifier 2 is operated with high speed by a self-feedback operation.

The single-ended sense amplifier 3 includes a P-channel transistor QP2, an N-channel transistor QN2, and inverters INV5, INV6. The single-ended sense amplifier 3 reverses the driving signal A3 and then converts a level of the reverse signal to a predetermined level to output as a signal A5 to the differential amplifying circuits 4 and 5.

The transistors QP2, QN2 and the inverters INV5, INV6 in the single-ended sense amplifier 3 are connected to each other as are the transistors QP1, QN1 and the inverters INV3, INV4 in the single-ended sense amplifier 2. Consequently, the single-ended sense amplifier 3 has the same circuit structure as that of the single-ended sense amplifier 2.

The differential amplifying circuit 4 includes P-channel transistors QP3, QP4 and N-channel transistors QN3 to QN5 and supplies a signal A6 corresponding to a difference between the signals A4 and A5 to the inverter INV8. Specifically, the signal A6 output from the differential amplifying circuit 4 is at a low level when the signal A4 is at a potential level lower than that of the signal A5, whereas the signal A6 is at a high level when the signal A4 is at a potential level higher than that of the signal A5.

The high power supply potential V_{DD2} is applied to sources of the transistors QP3 and QP4. A gate and a drain of the transistor QP3 and a gate of the transistor QP4 are connected to each other. A drain of the transistor QN3 is connected to the drain and the gate of the transistor QP3, and the signal A4 is supplied to a gate of the transistor QN3. A drain of the transistor QN4 is connected to a drain of the transistor QP4, and the signal AS is supplied to a gate of the transistor QN4. A potential at a junction between the drains of the transistors QN4 and QP4 is applied as a signal A6 to the inverter INV8.

The low power supply potential V_{SS} is applied to a source of the transistor QN5. A drain of the transistor QN5 is connected to sources of the transistors QN3 and QN4. Additionally, an enable signal EN1 is supplied to a gate of the transistor QN5, whereby the transistor QN5 is turned on when the enable signal EN1 is at a high level, so as to operate the differential amplifying circuit 4.

The differential amplifying circuit 5 includes P-channel transistors QP5, QP6, and N-channel transistors QN6 to QN8, and supplies a signal A7 corresponding to a difference between the signals A5 and A4 to the inverter INV7. Specifically, the signal A7 output from the differential amplifying circuit 5 is at a high level when the signal A4 is at a potential lower than that of the signal A5, whereas the signal A7 is at a low level when the signal A4 is at a potential higher than that of the signal A5.

The transistors QP5, QP6 and the transistors QN6 to QN8 in the differential amplifying circuit 5 are connected to each other as are the transistors QP3, QP4 and the transistors QN3 to QN5 in the differential amplifying circuit 4. Consequently, the differential amplifying circuit 5 has the same structure as that of the differential amplifying circuit 4.

The signal A7 is supplied to the inverter INV7, which in turn outputs a reverse signal of the signal A7 as a first output signal A8. The signal A6 is supplied to the inverter INV8, which in turn outputs a reverse signal of the signal A6 as a second output signal A8-bar.

In this case, when the potential V_{DD2} is larger than the potential V_{DD1}, the differential signal output circuit 1 serves as a step-up circuit. For example, when the potentials V_{SS}, V_{DD1}, and V_{DD2}, respectively, are 0V, 1.8V, and 2.5V, respectively, the first and the second output signals A8 and A8-bar having a level of 2.5V can be output based on the input signal A1 having a level of 1.8V.

Additionally, when the potential V_{DD1} is larger than the potential V_{DD2}, the differential signal output circuit 1 serves as a step-down circuit. For example, when the potentials V_{SS}, V_{DD2}, and V_{DD1}, respectively, are 0V, 1.8V, and 2.5V, respectively, the first and the second output signals A8 and A8-bar of 1.8V can be output based on the input signal A1 of 2.5V.

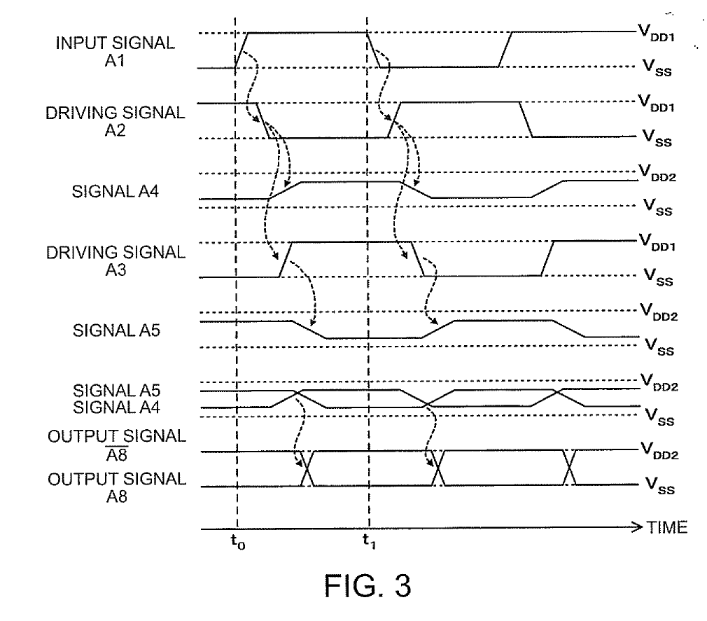

FIG. 3 is a timing chart showing an operation of the differential signal output circuit 1.

As shown in FIG. 3, when a potential of the input signal A1 changes from the low potential V_{SS} to the high potential V_{DD1} at time t₀, a potential of the driving signal A2 output from the inverter INV1 changes from the high potential V_{DD1} to the low potential V_{SS} after a predetermined delay time. When the potential of the driving signal A2 changes from the high potential V_{DD1} to the low potential V_{SS}, a potential of the signal A4 output from the single-ended sense amplifier 2 changes from a first potential level higher than the low potential V_{SS} to a second potential level higher than the first level and lower than the high potential V_{DD2}.

Meanwhile, when the potential of the driving signal A2 changes from the high potential V_{DD1} to the low potential V_{SS}, a potential of the driving signal A3 output from the inverter INV2 changes from the low potential V_{SS} to the high potential V_{DD1} after a predetermined delay time. Upon the potential change of the driving signal A3 from the low potential V_{SS} to the high potential V_{DD1}, a potential of the signal A5 output from the single-ended sense amplifier 3 changes from the second potential level to the first potential level.

At an initial time, the potential of the signal A4 is lower than that of the signal A5; the signal A7 output from the differential amplifying circuit 5 is at the high potential V_{DD2}; and the first output signal A8 output from the inverter INV7 is at the low potential V_{SS}. Additionally, the signal A6 output from the differential amplifying circuit 4 is at the low potential V_{SS}, and the second output signal A8-bar output from the inverter INV8 is at the high potential V_{DD2}.

After that, as described above, at time t₀, when the potential of the input signal A1 changes from the low potential V_{SS} to the high potential V_{DD1}, the potential of the signal A4 becomes higher than that of the signal A5. Thereby, the potential of the signal A7 changes from the high potential V_{DD2} to the low potential V_{SS}, and the potential of the first output signal A8 changes from the low potential V_{SS} to the high potential V_{DD2}. Additionally, the potential of the signal A6 changes from the low potential V_{SS} to the high potential V_{DD2}, and the potential of the second output signal A8-bar changes from the high potential V_{DD2} to the low potential V_{SS}.

Next, at time t₁, when the potential of the input signal A1 changes from the high potential V_{DD1} to the low potential V_{SS}, the potential of the driving signal A2 changes from the low potential V_{SS} to the high potential V_{DD1} after a predetermined delay time. Upon the potential change of the driving signal A2 from the low potential V_{SS} to the high potential V_{DD1}, the potential of the signal A4 output from the single-ended sense amplifier 2 changes from the second potential level to the first potential level.

Meanwhile, when the potential of the driving signal A2 changes from the low potential V_{SS} to the high potential V_{DD1}, the potential of the driving signal A3 output from the inverter INV2 changes from the high potential V_{DD1} to the low potential V_{SS} after a predetermined delay time. Upon the potential change of the driving signal A3 from the high potential V_{DD1} to the low potential V_{SS}, the potential of the signal A5 output from the single-ended sense amplifier 3 changes from the first potential level to the second potential level.

Accordingly, the potential of the signal A4 becomes lower than that of the signal A5; the potential of the signal A7 changes from the low potential V_{SS} to the high potential V_{DD1}; and the potential of the first output signal A8 changes from the high potential V_{DD2} to the low potential V_{SS}. Additionally, the potential of the signal A6 changes from the high potential V_{DD2} to the low potential V_{SS}, and the potential of the second output signal A8-bar output from the inverter INV8 changes from the low potential V_{SS} to the high potential V_{DD2}.

In this case, the differential amplifying circuits 4 and 5, respectively, output the signals A6 and A7, respectively, corresponding to a potential difference between the signals A4 and A5. Thus, no skew occurs between the signals A6 and A7. Consequently, no skew also occurs between the first and the second output signals A8 and A8-bar.

Occasionally, timings of changes in the signals A2 to A5 fluctuate due to production process variations, temperature fluctuations, fluctuations in power supply potentials (such as V_{DD1}, V_{DD2}, and V_{SS} in the embodiment), and the like. Even in that case, the differential amplifying circuits 4 and 5, respectively, output the signals A6 and A7, respectively, corresponding to the potential difference between the signals A4 and A5. Therefore, there is no skew between the first and the second output signals A8 and A8-bar even when the timings of changes in the signals A8 and A8-bar become earlier or later.

Additionally, the differential signal output circuit 1 does not require a capacitor, unlike the conventional differential signal output circuit (see FIG. 19 in Japanese Patent No. 3852447 above). This prevents yield reduction and the like.

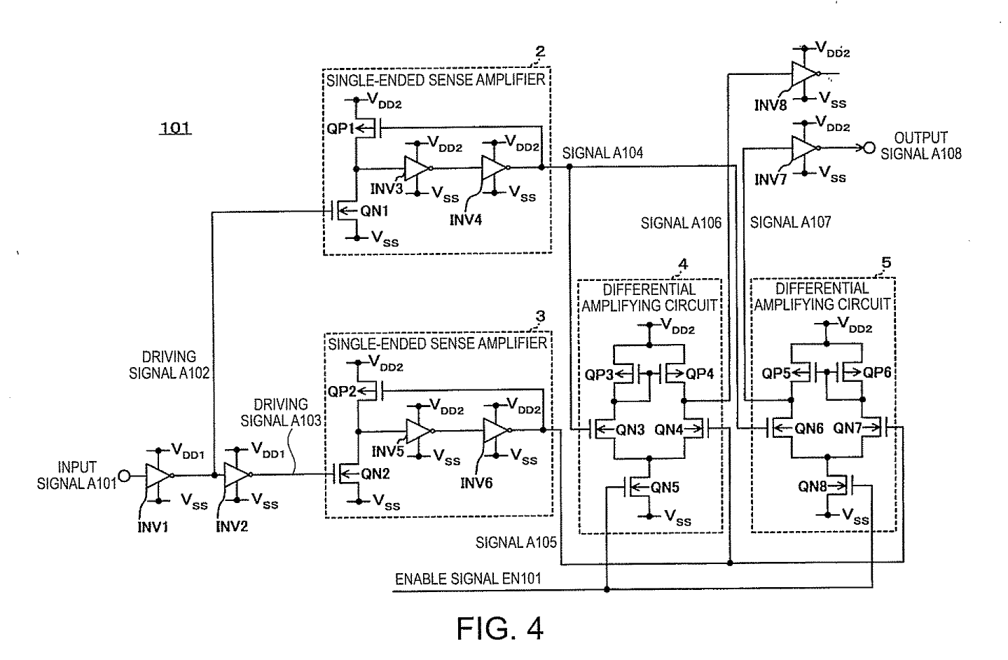

FIG. 4 is a diagram showing an example of an internal structure of the single signal output circuit 101 shown in FIG. 1. The single signal output circuit 101 outputs a single output signal (a forward signal in the embodiment) A108 based on an input signal A101, and includes the inverters INV1, INV2, INV7, and INV8, the single-ended sense amplifiers 2 and 3, and the current mirror differential amplifying circuits 4 and 5.

The inverters, the sense amplifiers, and the differential amplifying circuits in the single signal output circuit 101 are connected to each other as are those in the differential signal output circuit 1 (see FIG. 2). Accordingly, the single signal output circuit 101 has the same structure as that of the single signal output circuit 1, although the single signal output circuit 101 does not use the output signal of the inverter INV8.

As shown in FIG. 4, the input signal A101 is supplied to the inverter INV1, which in turn outputs a driving signal A102 as a reverse signal of the input signal A101. The driving signal A102 is supplied to the inverter INV2, which in turn outputs a driving signal A103 as a reverse signal of the input signal A102.

The single-ended sense amplifier 2 reverses the driving signal A102 and then converts a level of the reverse signal to a predetermined level to output as a signal A104 to the differential amplifying circuits 4 and 5.

The differential amplifying circuit 4 supplies a signal A106 corresponding to a difference between the signals A104 and A105 to the inverter INV8.

The differential amplifying circuit 5 supplies a signal A107 corresponding to a difference between the signals A105 and A104 to the inverter INV7.

The inverter INV7 reverses the supplied signal A107 to output as an output signal A108.

The signal A106 is supplied to the inverter INV8, which in turn reverses the signal A106.

In this case, when the potential V_{DD2} is larger than the potential V_{DD1}, the single signal output circuit 101 serves as a step-up circuit. For example, when the potentials V_{SS}, V_{DD1}, and V_{DD2}, respectively, are 0V, 1.8V, and 2.5V, respectively, the output signal A108 of 2.5V can be output based on the input signal A101 of 1.8V.

Additionally, when the potential V_{DD1} is larger than the potential V_{DD2}, the single signal output circuit 101 serves as a step-down circuit. For example, when the potentials V_{SS}, V_{DD2}, and V_{DD1,} respectively, are 0V, 1.8V, and 2.5V, respectively, the output signal A108 of 1.8V can be output based on the input signal A101 of 2.5V.

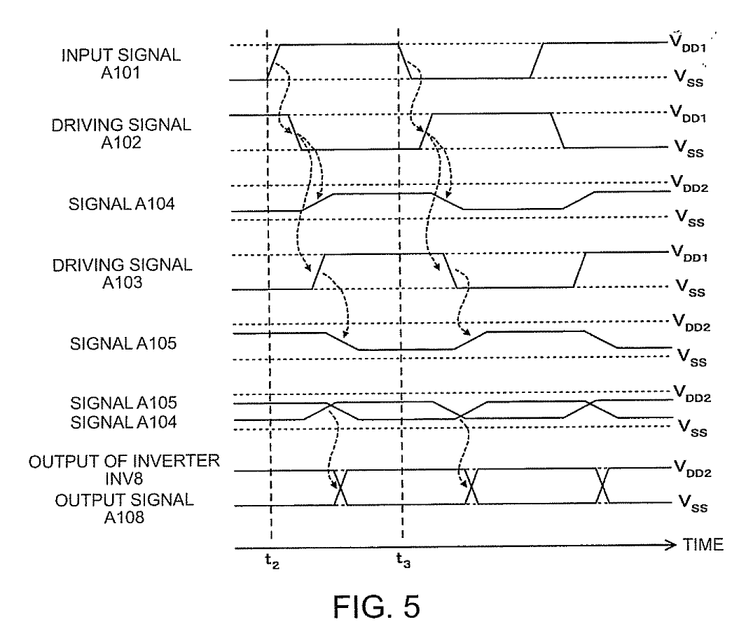

FIG. 5 is a timing chart showing an operation of the single signal output circuit 101.

As shown in FIG. 5, at time t₂, when a potential of the input signal A101 changes from the low potential V_{SS} to the high potential V_{DD1}, a potential of the driving signal A102 output from the inverter INV1 changes from the high potential V_{DD1} to the low potential V_{SS} after a predetermined delay time. Upon the potential change of the driving signal A102 from the high potential V_{DD1} to the low potential V_{SS}, a potential of the signal A104 output from the single-ended sense amplifier 2 changes from the first potential level higher than the low potential V_{SS} to the second potential level higher than the first level and lower than the high potential V_{DD2}.

Meanwhile, when the potential of the driving signal A102 changes from the high potential V_{DD1} to the low potential V_{SS}, a potential of the driving signal A103 output from the inverter INV2 changes from the low potential V_{SS} to the high potential V_{DD1} after a predetermined delay time. Upon the potential change of the driving signal A103 from the low potential V_{SS} to the high potential V_{DD1}, a potential of the signal A105 output from the single-ended sense amplifier 3 changes from the second potential level to the first potential level.

At an initial time, the potential of the signal A104 is lower than that of the signal A105; the signal A107 output from the differential amplifying circuit 5 is at the high potential V_{DD2}; and the first output signal A108 output from the inverter INV7 is at the low potential V_{SS}. Additionally, the signal A106 output from the differential amplifying circuit 4 is at the low potential V_{SS}, and the output signal from the inverter INV8 is at the high potential V_{DD2}.

After that, as described above, at time t₂, when the potential of the input signal A101 changes from the low potential V_{SS} to the high potential V_{DD1}, the potential of the signal A104 becomes higher than that of the signal A105. Thereby, the potential of the signal A107 changes from the high potential V_{DD2} to the low potential V_{SS}, and the potential of the output signal A108 changes from the low potential V_{SS} to the high potential V_{DD2}. The potential of the signal A106 changes from the low potential V_{SS} to the high potential V_{DD2}, and the potential of the output signal from the inverter INV8 changes from the high potential V_{DD2} to the low potential V_{SS}.

Next, at time t₃, when the potential of the input signal A101 changes from the high potential V_{DD1} to the low potential V_{SS}, the potential of the driving signal A102 changes from the low potential V_{SS} to the high potential V_{DD1} after a predetermined delay time. Upon the potential change of the driving signal A102 from the low potential V_{SS} to the high potential V_{DD1}, the potential of the signal A104 output from the single-ended sense amplifier 2 changes from the second potential level to the first potential level.

Meanwhile, when the potential of the driving signal A102 changes from the low potential V_{SS} to the high potential V_{DD1}, the potential of the driving signal A103 output from the inverter INV2 changes from the high potential V_{DD1} to the low potential V_{SS} after a predetermined delay time. Upon the potential change of the driving signal A103 from the high potential V_{DD1} to the low potential V_{SS}, the potential of the signal A105 output from the single-ended sense amplifier 3 changes from the first potential level to the second potential level.

Accordingly, the potential of the signal A104 becomes lower than that of the signal A105, and the level of the signal A107 changes from the low potential V_{SS} to the high potential V_{DD1}, whereas the potential of the output signal A108 changes from the high potential V_{DD2} to the low potential V_{SS}. Additionally, the potential of the signal A106 changes from the high potential V_{DD2} to the low potential V_{SS}, whereas the potential of the output signal from the inverter INV8 changes from the low potential V_{SS} to the high potential V_{DD2}.

In this case, the differential amplifying circuits 4 and 5, respectively, output the signals A106 and A107, respectively, corresponding to a potential difference between the signals A104 and A105. Thus, no skew occurs between the signals A106 and A107. Consequently, no skew also occurs between the output signal A108 and the output signal of the inverter INV8.

Timings of changes in the signals A102 to A105 occasionally fluctuate due to production process variations, temperature fluctuations, fluctuations in power supply potentials (such as V_{DD1}, V_{DD2}, and V_{SS} in the embodiment), and the like. Even in that case, the differential amplifying circuits 4 and 5 output the signals A106 and A107 corresponding to the potential difference between the signals A4 and A5. Therefore, there is no skew between the output signal A108 and the output signal of the inverter INV8 even when the timings of changes in the signal A108 and the output signal of the inverter INV8 become earlier or later.

As described above, the single signal output circuit 101 (see FIG. 4) has the same circuit structure as that of the differential signal output circuit 1 (see FIG. 2). Additionally, the timings of changes in the signals A2 to A5 and in the signals A102 to A105, respectively, occasionally fluctuate due to the production process variations, the temperature changes, the changes in power supply potentials, and the like. Even in that case, the differential amplifying circuits 4 and 5 of the differential signal output circuit 1 output the signals A6 and A7 corresponding to the potential difference between the signals A4 and A5, as well as the differential amplifying circuits 4 and 5 of the single signal output circuit 101 output the signals A106 and A107 corresponding to the potential difference between the signals A104 and A105. Accordingly, when the input signals A1 and A101 or the driving signals A2 and A102 change in the same timing (for example, when time t₀ in FIG. 3 and time t₂ in FIG. 5 are the same; when a falling time of the driving signal A2 in FIG. 3 is the same as that of the driving signal A102 in FIG. 5; when time t₁ in FIG. 3 is the same as time t₃ in FIG. 5; or when a rising time of the driving signal A2 in FIG. 3 is the same as that of the driving signal A102 in FIG. 5), the first and the second output signals A8 and the A8-bar of the differential signal output circuit 1 and the output signal A108 of the single signal output circuit 101 simultaneously or approximately simultaneously change, although the timings of the changes in the output signals A8 and A8-bar of the circuit 1 and the output signal A108 of the circuit 101 may become earlier or later. In other words, no skew occurs between the output signals A8 and A8-bar of the differential signal output circuit 1 and the output signal A108 of the single signal output circuit 101. Accordingly, a phase difference between the first and the second output signals A8 and A8-bar of the differential signal output circuit 1 and the output signal A108 of the single signal output circuit 101 is equal to or approximately equal to a phase difference between the input signals A1 and A101 or between the driving signals A2 and A102, thereby enabling reduction of phase difference fluctuations. This makes it unnecessary or easy to perform timing adjustment between the output signals A8 and A8-bar of the differential signal output circuit 1 and the output signal A108 of the single signal output circuit 101. In short, that makes it unnecessary or easy to equalize a delay amount of the output signal A108 and delay amounts of the differential signals A8 and A8-bar.

Additionally, the timings of the changes in the input signals A1 and A101 or the driving signals A2 and A102 may deviate from each other, namely, any phase difference may occur between the input signals A1 and A101 (for example, time t₀ in FIG. 3 is different from time t₂ in FIG. 5; the falling time of the driving signal A2 in FIG. 3 is different from that of the driving signal A102 in FIG. 5; time t₁ in FIG. 3 is different from time t₃ in FIG. 5; or the rising time of the driving signal A2 in FIG. 3 is different from that of the driving signal A102 in FIG. 5). In this case, when a deviation time is referred to as “T₀”, the deviation time between the timings of the changes in the first and the second output signals A8 and A8-bar of the differential signal output circuit 1 and the timings of the changes in the output signal A108 of the single signal output circuit 101 is equal to or approximately equal to T₀. In other words, the phase difference between the output signals A8 and A8-bar of the output circuit 1 and the output signal A108 of the output circuit 101 is equal to or approximately equal to the phase difference between the input signals A1 and A101 or between the driving signals A2 and A102, thereby enabling the reduction of phase difference fluctuations. This makes it unnecessary or easy to perform the timing adjustment between the first and the second output signals A8 and A8-bar of the differential signal output circuit 1 and the output signal A108 of the single signal output circuit 101. In short, that makes it unnecessary or easy to equalize the delay amount of the output signal A108 and the delay amounts of the differential signals.

The differential signal output circuit 1 and the single signal output circuit 101 have the same structure and thus can be used as same cells. This can facilitate architecture, management, and the like of a design library, as well as can facilitate a circuit design and the like of a product including the differential signal output circuit 1 and the single signal output circuit 101, such as a semiconductor integrated circuit.

Furthermore, the differential signal output circuit 1 does not require a capacitor, unlike the conventional differential signal output circuit (see FIG. 19 in Japanese Patent No. 3852447 above). This prevents yield reduction and the like.

Next will be described a second embodiment of the invention.

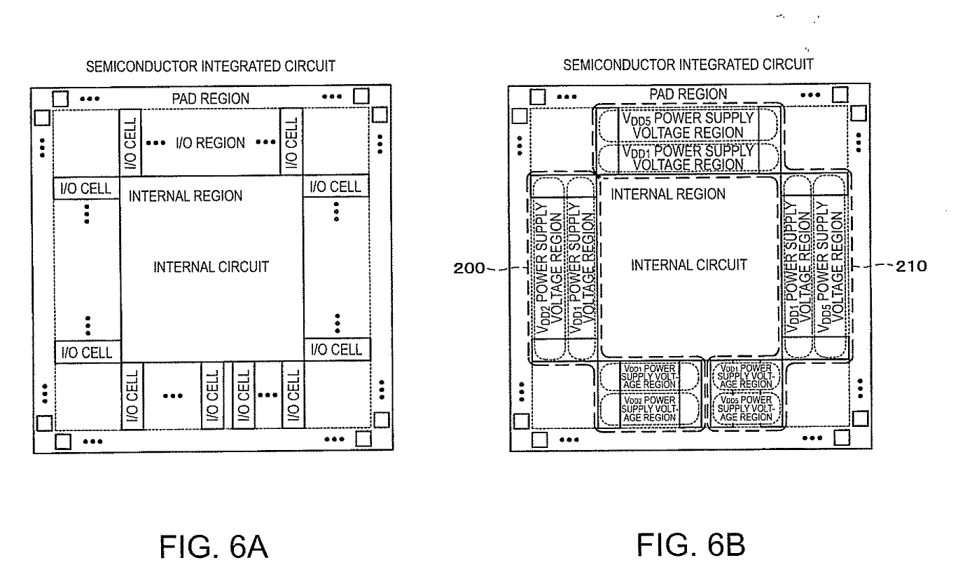

FIGS. 6A and 6B are schematic views showing a semiconductor integrated circuit according to the second embodiment.

As shown in FIG. 6A, the semiconductor integrated circuit includes an internal region (a core region), an input/output (I/O) region, and a pad region. The I/O region is formed outside the internal region. Specifically, the I/O region is formed so as to surround a periphery (four sides) of the internal region. The pad region is formed outside the I/O region, and specifically, formed so as to surround a periphery (four sides) of the I/O region. A pad arranged in the pad region may be arranged in the I/O region or the like, which makes the pad region unnecessary.

In the internal region is arranged an internal circuit (a core circuit) of the semiconductor integrated circuit. The internal circuit includes a central processing unit (CPU), a real-time clock (RTC), a display driver, a memory, an interface circuit, and various logic circuits. In the present embodiment, the internal circuit is operated by applying the high power supply potential V_{DD1} and the low power supply potential V_{SS}.

In the I/O region are arranged a plurality of I/O cells (such as an input cell, an output cell, an input/output cell, and a power supply cell). Specifically, for example, the I/O cells are arranged so as to surround an outer periphery (sides) of the internal circuit. In the pad region is arranged each pad connected to each of the I/O cells. Arrangements of the internal region, the I/O region, the pad region, the I/O cells, and the pads are not restricted to those shown in FIG. 6A and various modifications can be made.

FIG. 6B is a diagram showing a detail of the I/O region of the semiconductor integrated circuit shown in FIG. 6A.

As shown in FIG. 6B, the I/O region includes a plurality (two in the embodiment) of I/O cell regions (generally, circuit regions) 200 and 210, each having separate power supplies. The power supplies can be separated by separation of wells, separation of power-supply potential supply wirings, the separations of both the wells and the wirings, or other known methods. Alternatively, the semiconductor integrated circuit may include three or more I/O cell regions, each having separate power supplies.

The I/O cell region 200 is arranged from a left side of a chip to approximately a middle part of a lower side of the chip, whereas the I/O cell region 210 is arranged from an upper side of the chip to approximately the middle part of the lower side of the chip through a right side thereof.

On an internal peripheral side of the I/O cell region 200 (on a side thereof facing the internal region) is arranged a V_{DD1} power supply voltage region (generally, a power supply voltage region) where the high potential V_{DD1} is applied. Additionally, on an external peripheral side of the I/O cell region 200 (on a side thereof facing the pad region) is arranged a V_{DD2} power supply voltage region (generally, a power supply voltage region) where the high potential V_{DD2} is applied. Each I/O cell in the I/O cell region 200 is formed so as to straddle the power supply voltage regions of V_{DD1} and V_{DD2} to send and receive a signal having a level of the high potential V_{DD1} to and from the internal circuit, as well as to send and receive a signal having a level of the high potential V_{DD2} to and from a circuit outside the chip via the pad.

On an internal peripheral side of the I/O cell region 210 (on a side thereof facing the internal region) is arranged a V_{DD1} power supply voltage region (generally, a power supply voltage region) where the high potential V_{DD1} is applied. Additionally, on an external peripheral side of the I/O cell region 210 (on a side thereof facing the pad region) is arranged a V_{DD5} power supply voltage region (generally, a power supply voltage region) where a high potential V_{DD5} is applied. Each I/O cell in the I/O cell region 210 is formed so as to straddle the power supply voltage regions of V_{DD1} and V_{DD5}, whereby each cell sends and receives a signal of the high potential V_{DD1} to and from the internal circuit, as well as sends and receives a signal of the high potential V_{DD5} to and from a circuit outside the chip via the pad.

The high power supply potentials V_{DD5} and V_{DD2} may be different from or the same as each other. When V_{DD5} is different from V_{DD2}, signals having a plurality of potential levels can be transmitted between the semiconductor integrated circuit and an external circuit.

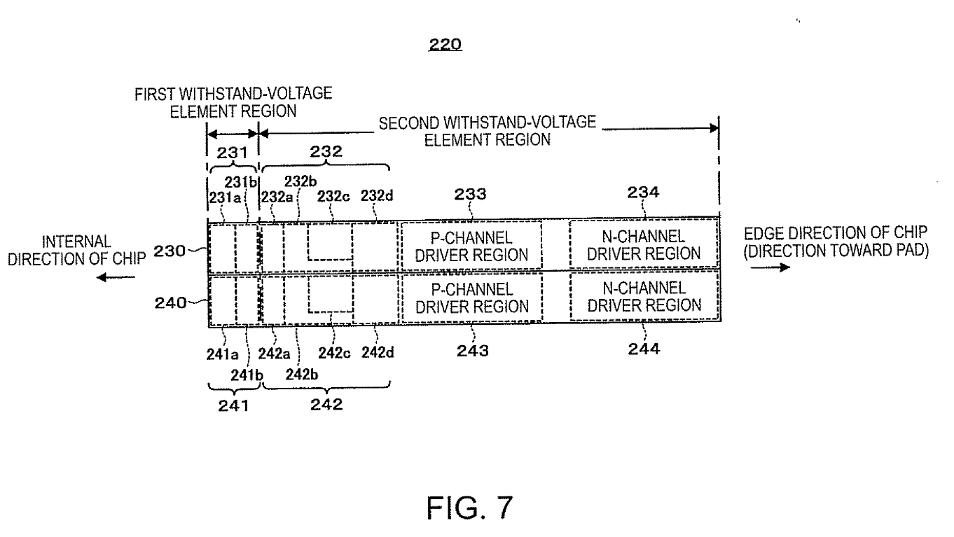

FIG. 7 is a diagram showing an example of layout of the I/O cells arranged in the I/O cell region 200.

As shown in FIG. 7, an I/O cell 220 includes a first slot 230 and a second slot 240. The first slot 230 is an output slot that outputs a signal inside the chip to an outside thereof, and the second slot 240 is an input slot that receives a signal outside the chip to supply the signal into the chip. The first and the second slots 230 and 240 each include a first withstand-voltage element region for arranging a first withstand-voltage element having a first withstand voltage (V_{DD1} in the embodiment) and a second withstand-voltage element region for arranging a second withstand-voltage element having a second withstand voltage (V_{DD2} in the embodiment). The first withstand-voltage element region corresponds to the V_{DD1} power supply voltage region in FIG. 6B, and the second withstand-voltage element region corresponds to the V_{DD2} power supply voltage region in FIG. 6B.

The first slot 230 has a function pre-driver region 231 in the first withstand-voltage element region and also has a pre-driver region 232, a P-channel driver region 233, and an N-channel driver region 234 in the second withstand-voltage element region. The function pre-driver region 231 has an N-channel transistor region 231a and a P-channel transistor region 231b. The pre-driver region 232 has a P-channel transistor region 232a, an N-channel transistor region 232b, a pull-down transistor region 232c, and a pull-up transistor region 232d.

In the pull-down transistor region 232c is arranged a pull-down N-channel transistor that has an ON resistance larger than that of an N-channel transistor arranged in the N-channel transistor region 232b.

In the pull-up transistor region 232d is arranged a pull-up P-channel transistor that has an ON resistance larger than that of a P-channel transistor arranged in the P-channel transistor region 232a.

In the P-channel driver region 233 is arranged a P-channel driver transistor, and in the N-channel driver region 234 is arranged an N-channel driver transistor.

The second slot 240 has an N-channel transistor region 241a and a P-channel transistor region 241b in the first withstand-voltage element region and also has an input buffer region 242, a P-channel driver region 243, and an N-channel driver region 244 in the second withstand-voltage element region. The input buffer region 242 has a P-channel transistor region 242a, an N-channel transistor region 242b, a pull-down transistor region 242c, and a pull-up transistor region 242d.

In the pull-down transistor region 242c is arranged a pull-down N-channel transistor that has an ON resistance larger than that of an N-channel transistor arranged in the N-channel transistor region 242b.

In the pull-up transistor region 242d is arranged a pull-up P-channel transistor that has an ON resistance larger than that of a P-channel transistor arranged in the P-channel transistor region 242a.

In the P-channel driver region 243 is arranged a P-channel driver transistor, and in the N-channel driver region 244 is arranged an N-channel driver transistor.

Preferably, transistors arranged in the first withstand-voltage element region are used as transistors included in the inverters INV1 and INV2 of the differential signal output circuit 1 (see FIG. 2). Additionally, it is preferable to use the transistors arranged in the second withstand-voltage element region as those included in the single-ended sense amplifiers 2, 3, the differential amplifying circuits 4, 5, and the inverters INV7, INV8 of the differential signal output circuit 1.

Similarly, preferably, the transistors arranged in the first withstand-voltage element region are used as those included in the inverters INV1 and INV2 of the single signal output circuit 101 (see FIG. 4). Additionally, it is preferable to use the transistors arranged in the second withstand-voltage element region as those included in the single-ended sense amplifiers 2, 3, the differential amplifying circuits 4, 5, and the inverters INV7, INV8 of the single signal output circuit 101.

In other words, preferably, the differential signal output circuit 1 and the single signal output circuit 101 are arranged in a same I/O cell region (in the I/O cell region 200 in the embodiment (see FIG. 6B). Operational conditions of both circuits are approximately the same in a same die or in the same I/O cell region. This makes it easier to provide a design guarantee against production process fluctuations, power supply potential fluctuations, and operational temperature fluctuations.

Furthermore, the embodiment facilitates a chip layout.

Examples of applications of the semiconductor integrated circuit as above include double data rate (DDR) standards and DDR2 standards.

In the DDR standards, a clock (CK) signal and a CK-bar signal can be output by the differential signal output circuit 1; a data (DQ) signal can be output by the single signal output circuit 101 including a plurality of single signal output circuits; and a data strobe (DQS) signal can be output by the single signal output circuit 101.

In the DDR2 standards, a clock (CK) signal and a CK-bar signal can be output by the differential signal output circuit 1; a data (DQ) signal can be output by the single signal output circuit 101 including a plurality of single signal output circuits; and a data strobe (DQS) signal and a DQS-bar signal can be output by the differential signal output circuit 1.

In both of the DDR and the DDR2 standards, requirements against signal delay and phase deviation are extremely strict. However, using the embodiment enables such strict requirements in the standards to be satisfied.

Next will be described a third embodiment of the invention.

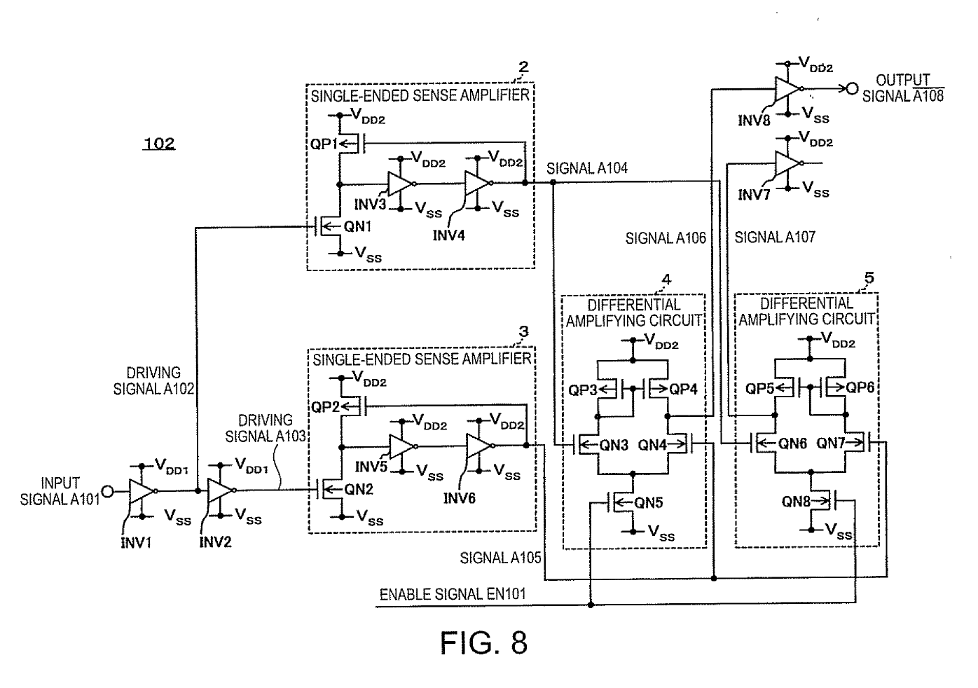

FIG. 8 is a diagram showing a structural example of a single signal output circuit according to the third embodiment. A single signal output circuit 102 shown in FIG. 8 outputs a single output signal (a reverse signal in the embodiment) A118-bar based on the input signal A101. The single signal output circuit 102 includes the inverters INV1, INV2, INV7, and INV8, the single-ended sense amplifiers 2, 3, and the current mirror differential amplifying circuits 4, 5.

The inverters, the sense amplifiers, and the differential amplifying circuits of the single signal output circuit 102 are connected to each other as are those included in the single signal output circuit 101 (see FIG. 4) described above. Consequently, the single signal output circuit 102 has the same circuit structure as that of the single signal output circuit 101.

However, unlike the single signal output circuit 101, the single signal output circuit 102 uses the output signal of the inverter INV8 as a reverse output signal A108-bar and does not use the output signal of the inverter INV7. This enables output of the reverse output signal A108-bar obtained by reversing a phase of the input signal A101.

In FIG. 8, a gate of the QN8 is connected to the enable signal EN101. However, the differential amplifying circuit 5 only adjusts a load balance between the signals A104 and A105 in circuit operation. Thus, the gate of the QNS may be functionally connected to the potential V_{SS} or V_{DD2} and preferably is connected to V_{SS} in terms of power consumption. This prevents unnecessary operations of the differential amplifying circuit 5 and the inverter INV7, thereby resulting in reduction of power consumption.

Next will be described a fourth embodiment of the invention.

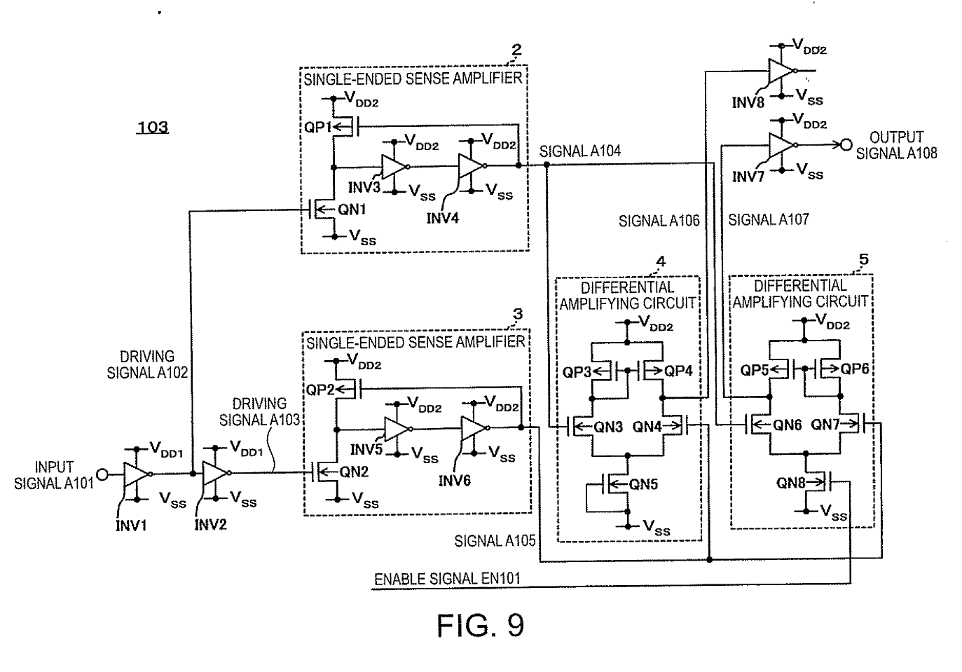

FIG. 9 is a diagram showing a structural example of a single signal output circuit according to the fourth embodiment. A single signal output circuit 103 shown in FIG. 9 outputs a single output signal (a forward signal in the embodiment) A108 based on the input signal A101. The single signal output circuit 103 includes the inverters INV1, INV2, INV7, and INV8, the single-ended sense amplifiers 2, 3, and the current mirror differential amplifying circuits 4, 5.

The inverters, the sense amplifiers, and the differential amplifying circuits of the single signal output circuit 103 are connected to each other as are those of the single signal output circuit 101 (see FIG. 4) described above. Consequently, the single signal output circuit 103 has the same circuit structure as that of the single signal output circuit 101.

In the present embodiment, the gate of the transistor QN5 is connected to the low power supply potential V_{SS} and thus the differential amplifying circuit 4 serves as a dummy circuit. Thereby, electrical current flowing through the differential amplifying circuit 4 can be turned off, so that power consumption of the single signal output circuit 103 can be made lower than that of the single signal output circuit 101. Alternatively, the gate of the transistor QN5 may be connected to the high power supply potential V_{DD2}. Preferably, the gate of QN5 is connected to V_{SS} in terms of power consumption.

Additionally, in the fourth embodiment, there is provided no wiring for supplying the enable signal EN101 to the gate of the transistor QN5 in the differential amplifying circuit 4. Alternatively, any other wiring such as one or more wirings may not be provided on a path from the high potential V_{DD2} to the low potential V_{SS} in the differential amplifying circuit 4 to turn off the differential amplifying circuit 4 so as to inhibit electrical current from flowing through the circuit 4.

In addition, there may not be provided any wiring for supplying the high power supply potential V_{DD2} or the low power supply potential V_{SS} to the inverter INV8. Thereby, electrical current flowing through the inverter INV8 is turned off, thus resulting in further reduction of power consumption in the single signal output circuit 103.

Next will be described a fifth embodiment of the invention.

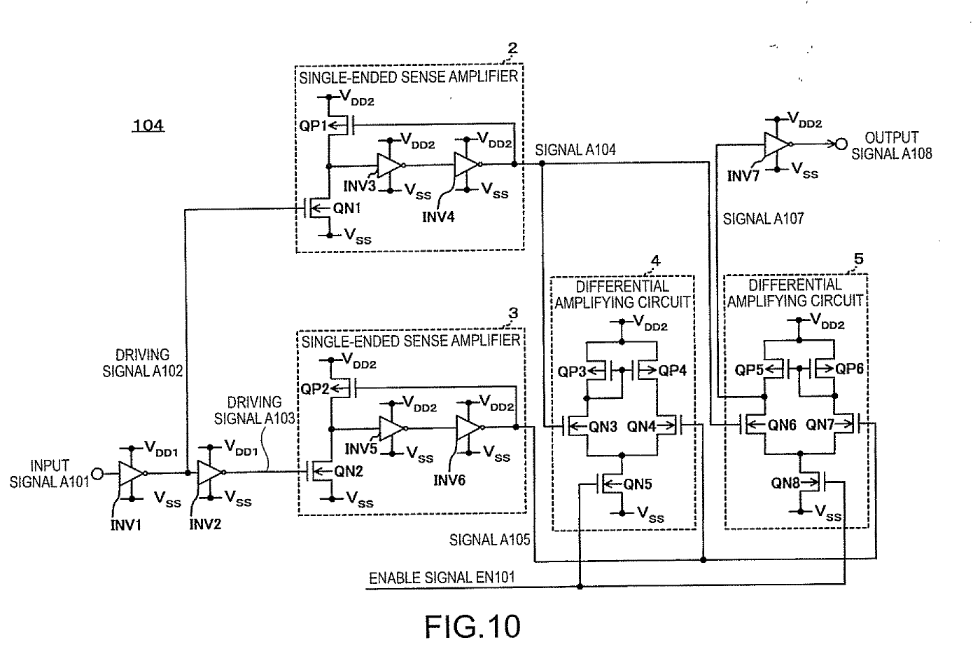

FIG. 10 is a diagram showing a structural example of a single signal output circuit according to the fifth embodiment. A single signal output circuit 104 shown in FIG. 10 outputs a single output signal (a forward signal in the embodiment) A108 based on the input signal A101. The single signal output circuit 104 includes the inverters INV1, INV2, and INV7, the single-ended sense amplifiers 2, 3, and the current mirror differential amplifying circuits 4, 5.

The inverters, the sense amplifiers, and the differential amplifying circuits of the single signal output circuit 104 are connected to each other as are those of the single signal output circuit 101 above.

Unlike the single signal output circuit 101, the single signal output circuit 104 does not include the inverter INV8. This can reduce the number of elements, and a size and power consumption of the single signal output circuit 104 as compared with the single signal output circuit 101. Additionally, when outputting the reverse output signal A108-bar obtained by reversing the phase of the input signal A101, the inverter INV7 may be eliminated instead of the inverter INV8.

In FIG. 10, the gate of the QN5 is connected to the enable signal EN101. However, the differential amplifying circuit 5 only adjusts a load balance between the signals A104 and A105 in circuit operation, and thus may be functionally connected to V_{SS} or V_{DD2}. Preferably, the differential amplifying circuit 5 is connected to V_{SS} in terms of power consumption.

Next will be described a sixth embodiment of the invention.

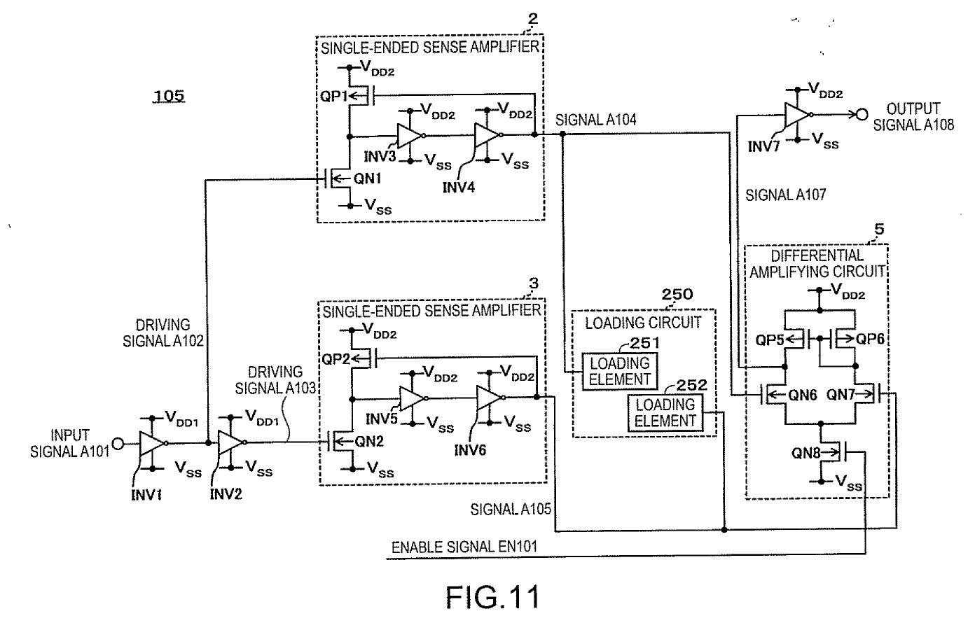

FIG. 11 is a diagram showing a structural example of a single signal output circuit according to the sixth embodiment. A single signal output circuit 105 shown in FIG. 11 outputs a single output signal (a forward signal in the embodiment) A108 based on the input signal A101. The single signal output circuit 105 includes the inverters INV1, INV2, and INV7, the single-ended sense amplifiers 2, 3, and the current mirror differential amplifying circuit 5, and a loading circuit 250. In this case, the single signal output circuit 105 has the loading circuit 250 instead of the differential amplifying circuit 4 included in the single signal output circuit 104 (see FIG. 10) described above.

The inverters, the sense amplifiers, and the differential amplifying circuit of the single signal output circuit 105 are connected to each other as are those of the single signal output circuit 104 described above.

The loading circuit 250 has loading elements 251 and 252. The loading element 251 is connected to an output terminal of the single-ended sense amplifier 2, and the loading element 252 is connected to an output terminal of the single-ended sense amplifier 3.

In the embodiment, it is not only that the differential amplifying circuit 4 is eliminated, but also that the loading circuit 250 is provided instead of the differential amplifying circuit 4. The reason for this is as follows. Simply eliminating the differential amplifying circuit 4 can disrupt a load balance between the single-ended sense amplifiers 2 and 3, thereby possibly fluctuating an output timing of the output signal A108.

In order to maintain the load balance between the single-ended sense amplifiers 2 and 3, preferably, the transistor QN3 (see FIG. 10) is used as the loading element 251. The gate of the transistor QN3 used as the loading element 251 is connected to the output terminal of the single-ended sense amplifier 2. Alternatively, the loading element 251 may be an element such as a capacitor having the same capacitance as a gate capacitance of the transistor QN3.

Similarly, preferably, the transistor QN4 (see FIG. 10) is used as the loading element 252, and the gate of the transistor QN4 used as the loading element 252 is connected to the output terminal of the single-ended sense amplifier 3. Alternatively, the loading element 252 may be an element such as a capacitor having the same capacitance as a gate capacitance of the transistor QN4.

Next will be described a seventh embodiment of the invention.

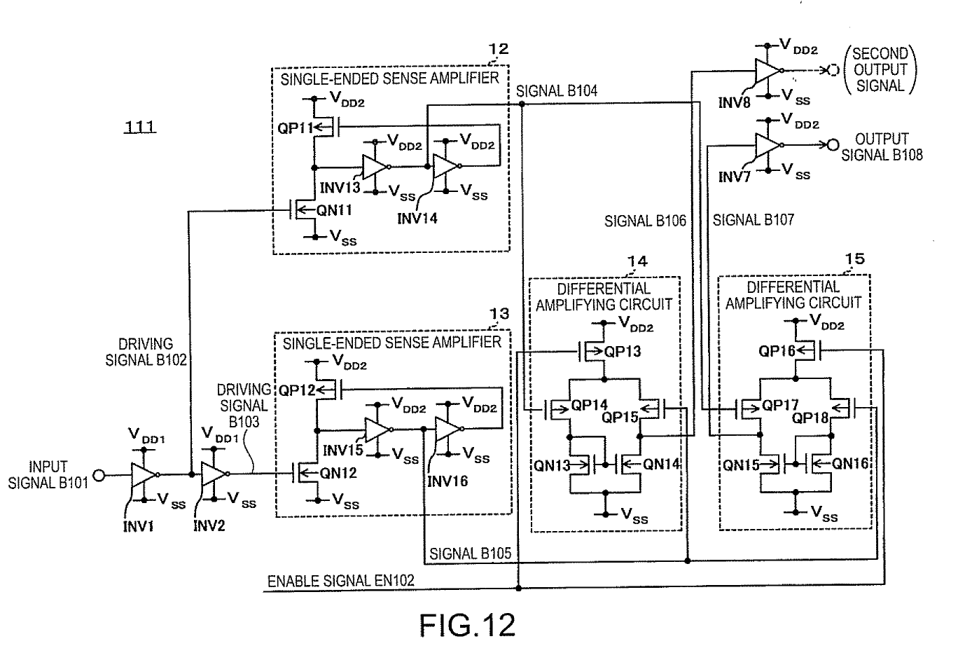

FIG. 12 is a diagram showing a structural example of a single signal output circuit according to the seventh embodiment. A single signal output circuit 111 shown in FIG. 12 outputs a single output signal (a forward signal in the embodiment) B108 based on an input signal B101. The single signal output circuit 111 includes the inverters INV1, INV2, INV7, and INV8, single-ended sense amplifiers 12, 13, and current mirror differential amplifying circuits 14, 15. Those inverters, sense amplifiers, and differential amplifying circuits are operated by applying the high power supply potential V_{DD2} and the low power supply potential V_{SS}.

A comparison between the single signal output circuit 111 and the single signal output circuit 101 (see FIG. 4) shows the following. In the single signal output circuit 101, the single-ended sense amplifier 2 outputs the signal A104 having a phase opposite to that of the driving signal A102, and the single-ended sense amplifier 3 outputs the signal A105 having a phase opposite to that of the driving signal A103. Meanwhile, in the single signal output circuit 111, the single-ended sense amplifier 12 outputs a signal B104 having the same phase as that of a driving signal B102, and the single-ended sense amplifier 13 outputs a signal B105 having the same phase as that of a driving signal B103. Additionally, polarities of the potentials V_{DD2} and V_{SS}, in the differential amplifying circuits 14 and 15 of the single signal output circuit 111 are reversed with respect to those in the differential amplifying circuits 4 and 5 of the single signal output circuit 101.

The single signal output circuit 111 outputs an output signal B108 in the same manner as in the single signal output circuit 101. In order to output a reverse output signal obtained by reversing a phase of the input signal B101, the output signal of the inverter INV8 may be used instead of the output signal of the inverter INV7.

Furthermore, using the output signal of the inverter INV8 in addition to the output signal of the inverter INV7 enables the single signal output circuit 101 in FIG. 12 to be used as a differential signal output circuit.

In FIG. 12, a gate of a QP13 is connected to an enable signal EN102. When no second output signal is used, the differential amplifying circuit 14 only adjusts a load balance between the signals B104 and B105 in circuit operation. Thus, the gate of the QP13 may be functionally connected to the potential V_{SS} or V_{DD2}. Preferably, the gate thereof is connected to the potential V_{SS} in terms of power consumption.

Next will be described an eighth embodiment of the invention.

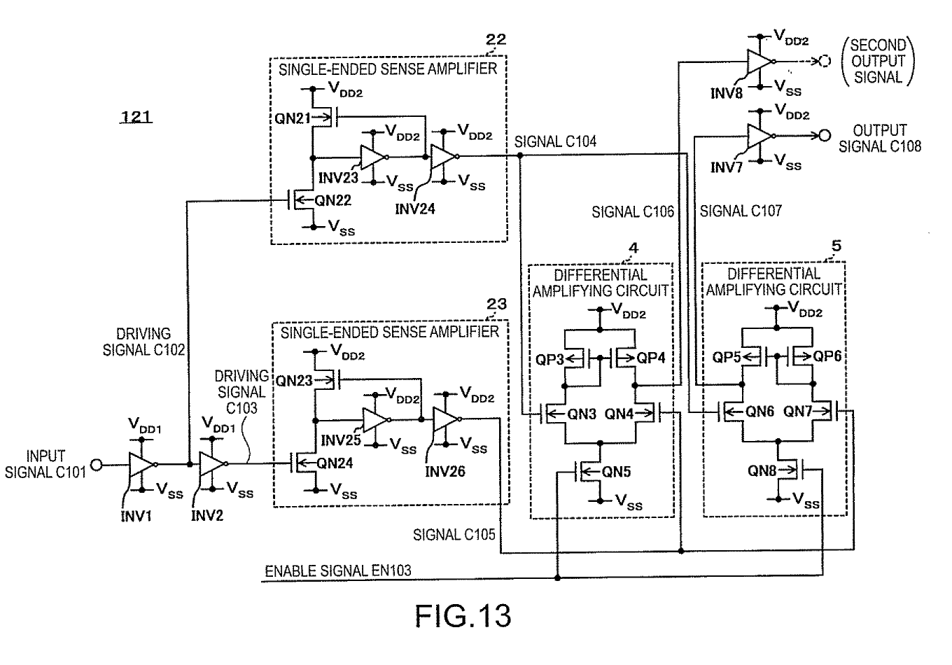

FIG. 13 is a diagram showing a structural example of a single signal output circuit according to the eighth embodiment. A single signal output circuit 121 shown in FIG. 13 outputs a single output signal (a forward signal in the embodiment) C108 based on an input signal C101. The single signal output circuit 121 includes the inverters INV1, INV2, INV7, and INV8, single-ended sense amplifiers 22, 23, and the current mirror differential amplifying circuits 4, 5. The single-ended sense amplifiers 22 and 23 are operated by applying the high power supply potential V_{DD2} and the low power supply potential V_{SS}.

A comparison of the single signal output circuit 121 with the single signal output circuit 111 (see FIG. 12) described above shows that the single-ended sense amplifiers 22 and 23 have a different structure. The single-ended sense amplifier 22 includes N-channel transistors QN21, QN22, and inverters INV23, INV24 to supply a signal C104 as a reverse signal of a driving signal C102 to the differential amplifying circuits 4, 5.

Source-to-drain paths of the transistors QN21 and QN22 are connected in series between the high potential V_{DD2} and the low potential V_{SS}. The driving signal C102 is supplied to a gate of the transistor QN22. A junction between the transistors QN21 and QN22 is connected to an input terminal of the inverter INV23.

An output terminal of the inverter INV23 is connected to a gate of the transistor QN21. The transistor QN21 constitutes a negative feedback loop from the output terminal to the input terminal of the inverter INV23. Accordingly, a level of a signal output from the inverter INV23 corresponds to a gain of the above feedback loop. The output signal of the inverter INV23 is supplied to the inverter INV24. The inverter INV24 supplies the signal C104 as a reverse signal of the output signal of the inverter INV23 to the differential amplifying circuits 4 and 5.

The single-ended sense amplifier 23 includes N-channel transistors QN23, QN24, and inverters INV25, INV26 to supply a signal C105 as a reverse signal of the driving signal C103 to the differential amplifying circuits 4 and 5. Those transistors and inverters of the single-ended sense amplifier 23 are connected to each other as are those of the single-ended sense amplifier 22. Thus, the single-ended sense amplifier 23 has the same circuit structure as that of the single-ended sense amplifier 22.

In the same manner as in the single signal output circuit 111, the single signal output circuit 121 outputs the output signal C108. When outputting a reverse output signal having a phase opposite to that of the input signal C101, the output signal of the inverter INV8 may be used instead of the output signal of the inverter INV7.

Using the output signal of the inverter INV8 in addition to the output signal of the inverter INV7 enables the circuit 121 in FIG. 13 to be used as a differential signal output circuit.

In FIG. 13, the gate of the QN5 is connected to an enable signal EN103. When no second output signal is used, the differential amplifying circuit 4 only adjusts a load balance between the signals C104 and C105 in circuit operation. Thus, the gate of the QN5 may-be functionally connected to the potential V_{SS} or V_{DD2}. Preferably, the gate thereof is connected to V_{SS} in terms of power consumption.

Next will be described a ninth embodiment of the invention.

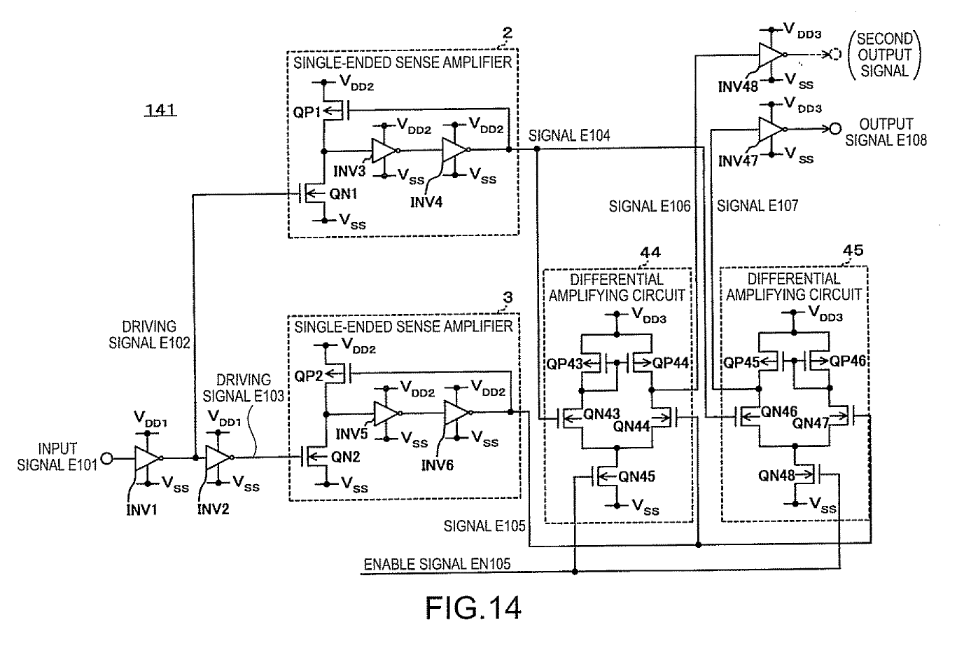

FIG. 14 is a diagram showing a structural example of a single signal output circuit according to the ninth embodiment. A single signal output circuit 141 in FIG. 14 outputs a single output signal (a forward signal in the embodiment) E108 based on an input signal 3101. The single signal output circuit 141 includes the inverters INV1, INV2, inverters INV47, INV48, the single-ended sense amplifiers 2, 3, and current mirror differential amplifying circuits 44, 45. The inverters INV47, INV48, and the current mirror differential amplifying circuits 44, 45 are operated by applying a power supply potential V_{DD3} at a high potential level (generally, a fourth power supply potential) and the low power supply potential V_{SS}.

The differential amplifying circuit 44 includes P-channel transistors QP43, QP44, and N-channel transistors QN43 to QN45, and has the same circuit structure as that of the differential amplifying circuit 4 of the single signal output circuit 101 (see FIG. 4) above. Similarly, the differential amplifying circuit 45 includes P-channel transistors QP45, QP46, and N-channel transistors QN46 to QN48, and has the same circuit structure as that of the differential amplifying circuit 5 of the single signal output circuit 101.

Unlike the single signal output circuit 101 above, in the single signal output circuit 141, the high potential V_{DD3} and the low potential V_{SS} are applied to the differential amplifying circuits 44, 45 and the inverters INV47, 48.

In this case, when V_{DD3} is larger than V_{DD2} and V_{DD2} is larger than V_{DD1}, the single signal output circuit 141 serves as a step-up circuit. As compared with the single signal output circuit 101, the single signal output circuit 141 is particularly effective when there is a large potential difference between the input signal E101 and the output signal E108.

For example, when the single signal output circuit 101 outputs the output signal A108 of 5V based on the input signal A101 of 1.8V, it is necessary to apply the potentials V_{SS} of 0V, V_{DD1} of 1.8V, and V_{DD2} of 5V. However, applying those power supply potentials causes the single-ended sense amplifiers 2 and 3 operated with the power supply potential of 5V to receive the driving signals A102 and A103 of 1.8V, whereby the amplifiers 2, 3 cannot perform intended operations.

Meanwhile, in the single signal output circuit 141, applying the potentials V_{SS} of 0V, V_{DD1} of 5V, V_{DD2} of 3.3V, and V_{DD3} of 1.8V facilitates output of the output signal E108 of 5V based on the input signal E101 of 1.8V.

Additionally, when V_{DD1} is larger than V_{DD2} and V_{DD2} is larger than V_{DD3}, the single signal output circuit 141 serves as a step-down circuit. As compared with the single signal output circuit 101, the single signal output circuit 141 is particularly effective when there is a large potential difference between the input signal E101 and the output signal E108.

For example, when the single signal output circuit 101 outputs the output signal A108 of 1.8V based on the input signal A101 of 5V, it is necessary to apply the potentials V_{SS} of 0V, V_{DD1} of 5V, and V_{DD2} of 1.8V. However, applying those power supply potentials causes the single-ended sense amplifiers 2 and 3 operated with the power supply potential of 1.8V to receive the driving signals A102 and A103 of 5V, which inhibits the amplifiers 2 and 3 from performing intended operations.

Meanwhile, in the single signal output circuit 141, applying the potentials V_{SS} of 0V, V_{DD1} of 5V, V_{DD2} of 3.3V, and V_{DD3} of 1.8V facilitates output of the output signal E108 of 1.8V based on the input signal E101 of 5V.

When outputting a reverse output signal obtained by reversing a phase of the input signal E101, the output signal of the inverter INV8 may be used instead of the output signal of the inverter INV7.

Using the output signal of the inverter INV48 in addition to the output signal of the inverter INV47 enables the output circuit 141 in FIG. 14 to be used as a differential signal output circuit.

In FIG. 14, a gate of the QN45 is connected to an enable signal EN105. When no second output signal is used, the differential amplifying circuit 44 only adjusts a load balance between the signals E104 and E105 in circuit operation. Thus, the gate of the QN45 may be functionally connected to the potential V_{SS} or V_{DD2}. Preferably, the gate thereof is connected to the potential V_{SS} in terms of power consumption.

Next will be described a tenth embodiment of the invention.

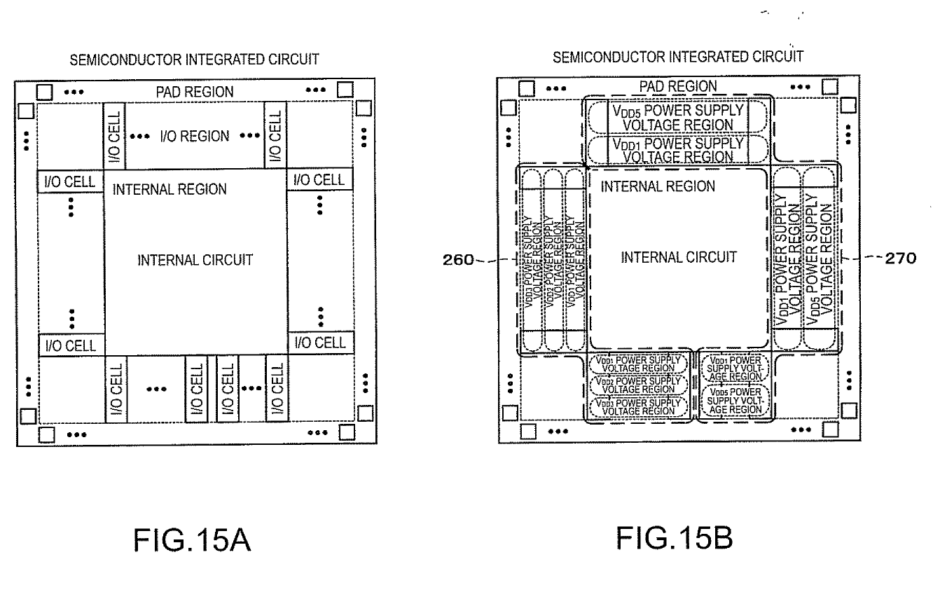

FIGS. 15A and 15B are schematic views showing a semiconductor integrated circuit according to the tenth embodiment.

As shown in FIG. 15A, the semiconductor integrated circuit includes an internal region (a core region), an I/O region, and a pad region. Arrangements of the internal region (the core region), the I/O region, and the pad region are the same as those in the semiconductor integrated circuit of the second embodiment (see FIG. 6A). In the present embodiment, the internal circuit is operated by applying the high power supply potential V_{DD1} and the low power supply potential V_{SS}.

FIG. 15B is a diagram showing a detail of the I/O region of the semiconductor integrated circuit in FIG. 15A.

As shown in FIG. 15B, the I/O region includes a plurality of I/O cell regions 260 and 270 (two in the embodiment), each having separate power supplies. Alternatively, the semiconductor integrated circuit may include three or more I/O cell regions, each having separate power supplies.

In the drawing, the I/O cell region 260 is arranged from a left side of a chip to approximately a middle part of a lower side of the chip, whereas the I/O cell region 270 is arranged from an upper side of the chip to approximately the middle part of the lower side of the chip through a right side thereof.

On an internal peripheral side of the I/O cell region 260 (on a side thereof facing the internal region) is arranged a V_{DD1} power supply voltage region (generally, a power supply voltage region) where the high power supply potential V_{DD1} is applied. Additionally, on an external peripheral side of the V_{DD1} power supply voltage region (on a side thereof toward the pad region) in the I/O cell region 260 is arranged a V_{DD2} power supply voltage region (generally, a power supply voltage region) where the high power supply potential V_{DD2} is applied. Furthermore, on an external peripheral side of the V_{DD2} power supply voltage region (on the side thereof toward the pad region) in the I/O cell region 260 is arranged a V_{DD3} power supply voltage region (generally, a power supply voltage region) where the high power supply potential V_{DD3} is applied. Each I/O cell in the I/O cell region 260 is formed so as to straddle the power supply voltage regions of V_{DD1}, V_{DD2}, and V_{DD3}, whereby each cell sends and receives a signal having a level of the high potential V_{DD1} to and from the internal circuit, as well as sends and receives a signal having a level of the high potential V_{DD3} to and from a circuit outside the chip via the pad.

On an internal peripheral side of the I/O cell region 270 (on a side thereof facing the internal region) is arranged a V_{DD1} power supply voltage region where the high potential V_{DD1} is applied. Additionally, on an external peripheral side of the I/O cell region 270 (on a side thereof facing the pad region) is arranged a V_{DD5} power supply voltage region where the high potential V_{DD5} is applied. Each I/O cell in the I/O cell region 270 is formed so as to straddle the V_{DD1} power supply voltage region and the V_{DD5} power supply voltage region, whereby each cell sends and receives a signal of the high potential V_{DD1} to and from the internal circuit, as well as sends and receives a signal of the high potential V_{DD5} to and from a circuit outside the chip via the pad.

The high potential V_{DD5} may be different from or the same as the high potentials V_{DD2} and V_{DD3}. When the potential V_{DD5} is made different from the potential V_{DD3}, signals having a plurality of potential levels can be transmitted between the semiconductor integrated circuit and an external circuit.

Furthermore, in the embodiment, the I/O cell region 270 has the two regions with the separate power supplies. However, the region 270 may have three or more regions with the separate power supplies.

Preferably, the transistors of the inverters INV1 and INV2 of the single signal output circuit 141 (see FIG. 14) are transistors arranged in the V_{DD1} power supply voltage region. Additionally, preferably, the transistors of the single-ended sense amplifiers 2 and 3 of the single signal output circuit 141 are transistors arranged in the V_{DD2} power supply voltage region. Furthermore, preferably, the transistors of the differential amplifying circuits 44, 45, and the inverters INV47, INV48 of the single signal output circuit 141 are transistors arranged in the V_{DD3} power supply voltage region.

Preferably, the transistors arranged in the V_{DD1} power supply voltage region are used as the transistors of the inverters INV1 and INV2 in a differential signal output circuit that additionally uses the output signal of the inverter INV48 in FIG. 14. Preferably, the transistors arranged in the V_{DD2} power supply voltage region are used as the transistors of the single-ended sense amplifiers 2 and 3 in the differential signal output circuit described above. Furthermore, the transistors arranged in the V_{DD3} power supply voltage region are used as the transistors in the differential amplifying circuits 44, 45, and the inverters INV47, INV48 in the differential signal output circuit described above.

In other words, preferably, both of the single signal output circuit 141 and the differential signal output circuit additionally using the output signal of the inverter INV48 in FIG. 14 are arranged in a same I/O cell region (in the I/O cell region 260 (see FIG. 15B) in the embodiment). Since operational conditions of both circuits in a same die or in a same I/O cell region are approximately the same, it is easier to provide a design guarantee against production process fluctuations, power source fluctuations, and operational temperature fluctuations.

Next will be described an eleventh embodiment of the invention.

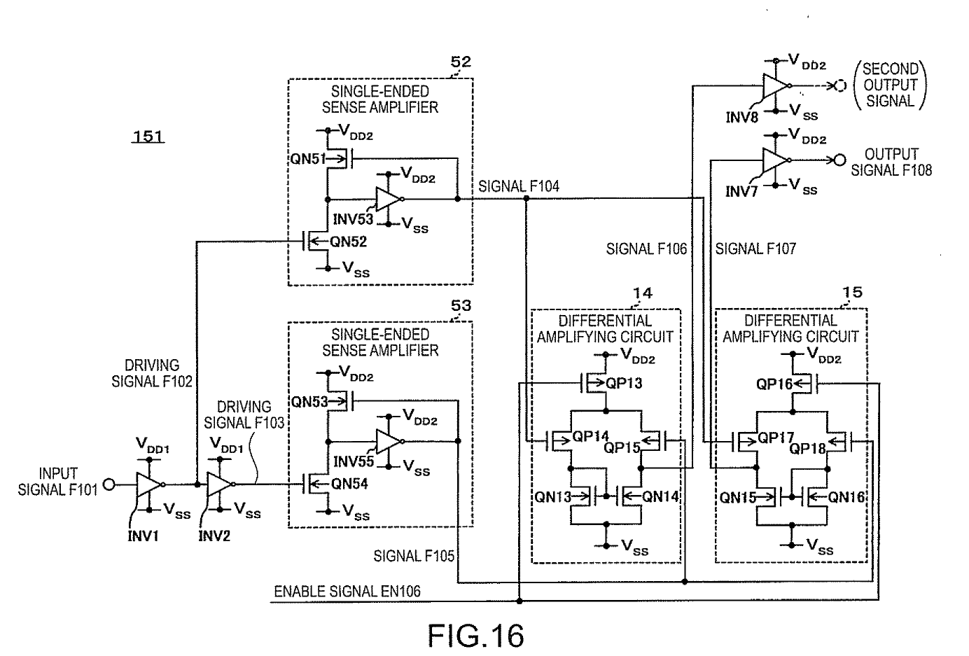

FIG. 16 is a diagram showing a structural example of a single signal output circuit according to the eleventh embodiment. A single signal output circuit 151 shown in FIG. 16 outputs a single output signal (a forward signal in the embodiment) F108 based on an input signal F101. The single signal output circuit 151 includes the inverters INV1, INV2, INV7, and INV8, single-ended sense amplifiers 52, 53, and the current mirror differential amplifying circuits 14, 15. The single-ended sense amplifiers 52, 53 are operated by applying the high power supply potential V_{DD2} and the low power supply potential V_{SS}.

When compared with the single signal output circuit 111 (see FIG. 12) above, the single-ended sense amplifiers 52 and 53 of the single signal output circuit 151 have a different structure. The single-ended sense amplifier 52 includes N-channel transistors QN51, QN52 and an inverter INV53 to supply a signal F104 obtained by converting a driving signal F102 to a signal having a predetermined potential level to the differential amplifying circuits 14, 15.

Source-to-drain paths of the transistors QN51 and QN52 are connected in series between the high potential V_{DD2} and the low potential V_{SS}. The driving signal F102 is supplied to a gate of the transistor QN52. A junction between the transistors QN51 and QN52 is connected to an input terminal of the inverter INV53.

An output terminal of the inverter INV53 is connected to a gate of the transistor QN51. The transistor QN51 constitutes a negative feedback loop from the output terminal of the inverter INV53 to an input terminal thereof. Accordingly, a level of the signal F104 output from the inverter INV53 corresponds to a gain of the above feedback loop.

Additionally, the single-ended sense amplifier 53 includes N-channel transistors QN53, QN54 and an inverter INV55 to supply a signal F105 obtained by converting a driving signal F103 to a signal having a predetermined level to the differential amplifying circuits 14, 15.

The transistors and the inverter of the single-ended sense amplifier 53 are connected to each other as are those of the transistors and the inverter of the single-ended sense amplifier 52. Consequently, the single-ended sense amplifier 53 is structured as is the single-ended sense amplifier 52.

In this manner, the single signal output circuit 151 has the same functionality as that of the single signal output circuit 111, while using a smaller number of the elements than in the single signal output circuit 111.

Using additionally the output signal of the inverter INV8 enables the circuit 151 in FIG. 16 to be used as a differential signal output circuit.

In FIG. 16, the gate of the QP13 is connected to an enable signal EN106. When no second output signal is used, the differential amplifying circuit 14 only adjusts a load balance between the signals F104 and F105 in circuit operation. Thus, the gate of the QP13 may be functionally connected to the potential V_{SS} or V_{DD2}. Preferably, the gate thereof is connected to the potential V_{SS} in terms of power consumption.

Next will be described a twelfth embodiment of the invention.

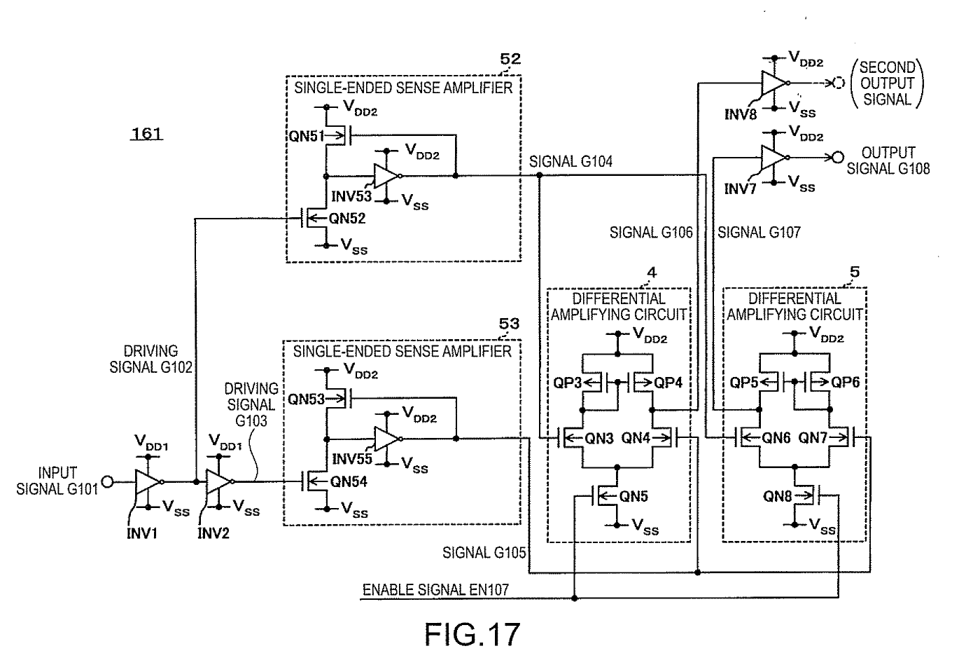

FIG. 17 is a diagram showing a structural example of a single signal output circuit according to the twelfth embodiment. A single signal output circuit 161 shown in FIG. 17 outputs a single output signal (a forward signal in the embodiment) G108 based on an input signal G101. The single signal output circuit 161 includes the inverters INV1, INV2, INV7, and INV8, the single-ended sense amplifiers 52, 53, and the current mirror differential amplifying circuits 4, 5.

When compared with the single signal output circuit 101 (see FIG. 4) described above, the single-ended sense amplifiers 52 and 53 of the single signal output circuit 161 each have a different structure.

In this manner, the single signal output circuit 161 has the same functionality as the single signal output circuit 101, while using a smaller number of the elements than in the single signal output circuit 101.

Using additionally the output signal of the inverter INV8 enables the circuit 161 in FIG. 17 to be used as a differential signal output circuit.

In FIG. 17, the gate of the QN5 is connected to an enable signal EN107. When no-second output signal is used, the differential amplifying circuit 4 only adjusts a load balance between the signals G104 and G105 in circuit operation. Thus, the gate of the QN5 may be functionally connected to the potential V_{SS} or V_{DD2}. Preferably, the gate thereof is connected to the potential V_{SS} in terms of power consumption.

Next will be described a thirteenth embodiment of the invention.

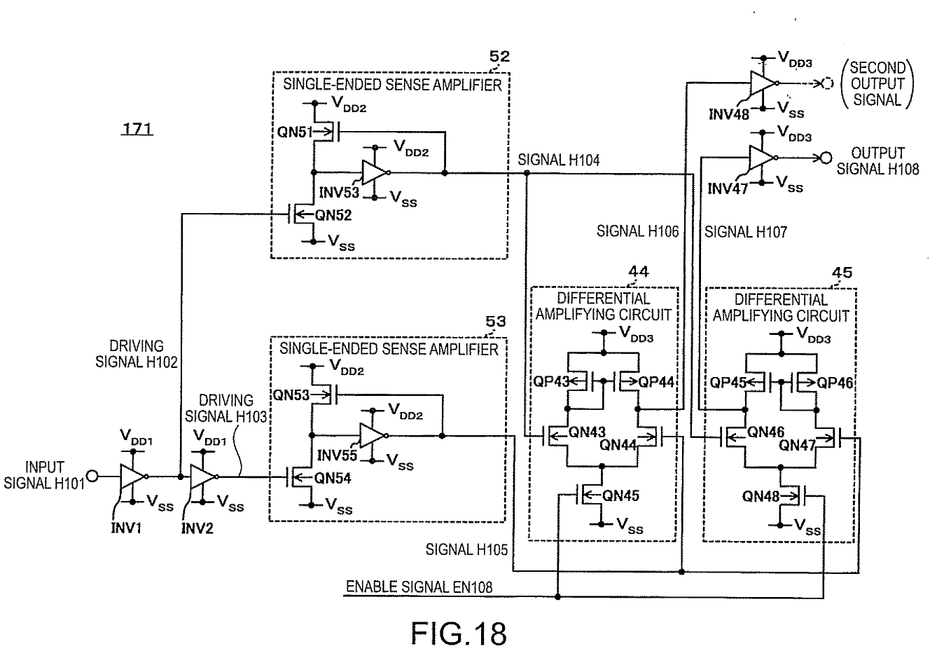

FIG. 18 is a diagram showing a structural example of a single signal output circuit according to the thirteenth embodiment. A single signal output circuit 171 shown in FIG. 18 outputs a single output signal (a forward signal in the embodiment) H108 based on an input signal H101. The single signal output circuit 171 includes the inverters INV1, INV2, INV47, and INV48, the single-ended sense amplifiers 52, 53, and the current mirror differential amplifying circuits 44, 45.

The single signal output circuit 171 uses the single-ended sense amplifiers 52, 53 of the single signal output circuit 151 (see FIG. 16) described above, as alternatives to the single-ended sense amplifiers 2, 3 of the single signal output circuit 141 (see FIG. 14) described above.

In the single signal output circuit 171, the same functionality as that of the single signal output circuit 141 can be achieved by using a smaller number of the elements than in the single signal output circuit 141.

Using additionally the output signal of the inverter INV8 enables the circuit 171 in FIG. 18 to be used as a differential signal output circuit.

In FIG. 18, the gate of the QN45 is connected to an enable signal EN108. When no second output signal is used, the differential amplifying circuit 44 only adjusts a load balance between the signals H104 and H105 in circuit operation. Thus, the gate of the QN45 may be functionally connected to the potential V_{SS} or V_{DD2}. Preferably, the gate thereof is connected to V_{SS} in terms of power consumption.

The present invention is not restricted to the embodiments described above, and various modifications can be made without departing from the scope of the invention. For example, the structure of the output circuit is not restricted to those described in FIGS. 2, 4, and the like, and can be modified in various forms.

In the descriptions of the specification and the drawings, terms such as “differential signal output circuit”, “single signal output circuit”, “inverter”, “single-ended sense amplifier”, and “current mirror differential amplifying circuit” are cited as representing general terms such as “output circuit”, “reverse circuit”, “signal level converting circuit”, and “differential circuit”. The terms cited can be replaced with such general terms in other descriptions of the specification and the drawings.

Furthermore, the embodiments according to dependent claims appended hereinbelow may not include part of constituent elements of claims on which the dependent claims depend. Additionally, a main part of the embodiment according to independent claim 1 may be made dependent on any other independent claim.

Still furthermore, it is to be understood that various embodiments of the invention can be applied to an output circuit that outputs a signal to an external circuit, an output circuit group, a semiconductor integrated circuit, and the like incorporating the output circuit group.

What is claimed is:

1. An output circuit group, comprising:
at least one first output circuit that outputs a pair of differential signals, the first output circuit including:
a first reversing circuit operated by applying a first power supply potential and a second power supply potential to reverse a first driving signal so as to output a first reverse driving signal;
a first signal level converting circuit operated by applying the first power supply potential and a third power supply potential to convert the first driving signal to a signal having a predetermined level to output;
a second signal level converting circuit operated by applying the first and the third power supply potentials to convert the first reverse driving signal to a signal having a predetermined level to output;
a first differential circuit operated by applying the first and the third power supply potentials to output a signal having a first polarity corresponding to a difference between the signal output from the first signal level converting circuit and the signal output from the second signal level converting circuit;
a second differential circuit operated by applying the first and the third power supply potentials to output a signal having a second polarity that is opposite to the first polarity and corresponding to a difference between the signal output from the second signal level converting circuit and the signal output from the first signal level converting circuit;
a first output signal generating circuit operated by applying the first and the third power supply potentials to generate a first output signal based on the signal having the first polarity output from the first differential circuit; and
a second output signal generating circuit operated by applying the first and the third power supply potentials to generate a second output signal based on the signal having the second polarity output from the second differential circuit, the first and the second output signals being included in the differential signals; and
at least one second output circuit that outputs a single forward or reverse signal, the second output circuit including:
a second reversing circuit operated by applying the first and the second power supply potentials to reverse a second driving signal so as to output a second reverse driving signal;
a third signal level converting circuit operated by applying the first and the third power supply potentials to convert the second driving signal to a signal having a predetermined level to output;
a fourth signal level converting circuit operated by applying the first and the third power supply potentials to convert the second reverse driving signal to a signal having a predetermined level to output;
a third differential circuit operated by applying the first and the third power supply potentials to output a signal having a first polarity corresponding to a difference between the signal output from the third signal level converting circuit and the signal output from the fourth signal level converting circuit;
a loading circuit connected to an output terminal of each of the third and the fourth signal level converting circuits to have a load capacitance approximately equal to a load capacitance of the third differential circuit; and
a third output signal generating circuit operated by applying the first and the third power supply potentials to generate the forward or reverse signal based on the signal having the first polarity output from the third differential circuit.

2. An output circuit group, comprising:
at least one first output circuit that outputs a pair of differential signals, the first output circuit including:
a first reversing circuit operated by applying a first power supply potential and a second power supply potential to reverse a first driving signal so as to output a first reverse driving signal;
a first signal level converting circuit operated by applying the first power supply potential and a third power supply potential to convert the first driving signal to a signal having a predetermined level to output;
a second signal level converting circuit operated by applying the first and the third power supply potentials to convert the first reverse driving signal to a signal having a predetermined level to output;
a first differential circuit operated by applying the first power supply potential and a fourth power supply potential to output a signal having a first polarity corresponding to a difference between the signal output from the first signal level converting circuit and the signal output from the second signal level converting circuit;
a second differential circuit operated by applying the first and the fourth power supply potentials to output a signal having a second polarity that is opposite to the first polarity and corresponding to a difference between the signal output from the second signal level converting circuit and the signal output from the first signal level converting circuit;
a first output signal generating circuit operated by applying the first and the fourth power supply potentials to generate a first output signal based on the signal having the first polarity output from the first differential circuit; and
a second output signal generating circuit operated by applying the first and the fourth power supply potentials to generate a second output signal based on the signal having the second polarity output from the second differential circuit, the first and the second output signals being included in the differential signals; and
at least one second output circuit that outputs a single forward or reverse signal, the second output circuit including:
a second reversing circuit operated by applying the first and the second power supply potentials to reverse a second driving signal so as to output a second reverse driving signal;
a third signal level converting circuit operated by applying the first and the third power supply potentials to convert the second driving signal to a signal having a predetermined level to output;
a fourth signal level converting circuit operated by applying the first and the third power supply potentials to convert the second reverse driving signal to a signal having a predetermined level to output;
a third differential circuit operated by applying the first and the fourth power supply potentials to output a signal having a first polarity corresponding to a difference between the signal output from the third signal level converting circuit and the signal output from the fourth signal level converting circuit;
a loading circuit connected to an output terminal of each of the third and the fourth signal level converting circuits to have a load capacitance approximately equal to a load capacitance of the third differential circuit; and
a third output signal generating circuit operated by applying the first and the fourth power supply potentials to generate the forward or reverse signal based on the signal having the first polarity output from the third differential circuit.

3. The output circuit group according to claim 2, wherein the third power supply potential is higher than the second power supply potential, and the fourth power supply potential is higher than the third power supply potential.

4. The output circuit group according to claim 2, wherein the third power supply potential is lower than the second power supply potential, and the fourth power supply potential is lower than the third power supply potential.

5. The output circuit group according to claim 1, wherein a phase difference between the first and the second driving signals is approximately equal to a phase difference between the differential signals output from the first output circuit and the forward or reverse signal output from the second output circuit.

6. The output circuit group according to claim 1, wherein the loading circuit is a dummy differential circuit having a structure approximately equal to a structure of the third differential circuit.

7. The output circuit group according to claim 1, wherein the loading circuit includes a first loading element having a load capacitance approximately equal to an input load capacitance of a first input terminal of the third differential circuit and a second loading element having a load capacitance approximately equal to an input load capacitance of a second input terminal of the third differential circuit.

8. A semiconductor integrated circuit, comprising:
a chip having a plurality of circuit regions formed thereon, each region having separate power supplies; and
the output circuit group according to claim 1, the output circuit group being formed in one of the circuit regions.

9. The semiconductor integrated circuit according to claim 8, wherein the one of the circuit regions having the output circuit group formed therein includes a plurality of power supply voltage regions formed in parallel in a side direction of the chip, and each of the first and the second output circuits included in the output circuit group is formed so as to straddle the power supply voltage regions.

10. An output circuit that outputs a single forward or reverse signal based on a driving signal, the output circuit comprising:
a reversing circuit operated by applying a first power supply potential and a second power supply potential to reverse the driving signal so as to output a reverse driving signal;
a first signal level converting circuit operated by applying the first power supply potential and a third power supply potential to convert the driving signal to a signal having a predetermined level to output;
a second signal level converting circuit by applying the first and the third power supply potentials to convert the reverse driving signal to a signal having a predetermined level to output;
a differential circuit operated by applying the first and the third power supply potentials to output a signal having a predetermined polarity corresponding to a difference between the signal output from the first signal level converting circuit and the signal output from the second signal level converting circuit;
a loading circuit connected to an output terminal of each of the first and the second signal level converting circuits to have a load capacitance approximately equal to a load capacitance of the differential circuit; and
an output signal generating circuit operated by applying the first and the third power supply potentials to generate the forward or reverse signal based on the signal having the predetermined polarity output from the differential circuit.

11. An output circuit that outputs a single forward or reverse signal based on a driving signal, the output circuit comprising:
a reversing circuit operated by applying a first power supply potential and a second power supply potential to reverse the driving signal so as to output a reverse driving signal;
a first signal level converting circuit operated by applying the first power supply potential and a third power supply potential to convert the driving signal to a signal having a predetermined level to output;
a second signal level converting circuit operated by applying the first and the third power supply potentials to convert the reverse driving signal to a signal having a predetermined level to output;
a differential circuit operated by applying the first power supply potential and a fourth power supply potential to output a signal having a predetermined polarity corresponding to a difference between the signal output from the first signal level converting circuit and the signal output from the second signal level converting circuit;
a loading circuit connected to an output terminal of each of the first and the second signal level converting circuits to have a load capacitance approximately equal to a load capacitance of the differential circuit; and
an output signal generating circuit operated by applying the first and the fourth power supply potentials to generate the forward or reverse signal based on the signal having the predetermined polarity output from the differential circuit.

12. The output circuit according to claim 11, wherein the loading circuit is a dummy differential circuit having a structure approximately equal to a structure of the differential circuit.

13. The output circuit according to claim 11, wherein the loading circuit includes a first loading element having a load capacitance approximately equal to an input load capacitance of a first input terminal of the differential circuit and a second loading element having a load capacitance approximately equal to an input load capacitance of a second input terminal of the differential circuit.

14. An output circuit group, comprising:
at least one first output circuit that outputs a pair of differential signals, the first output circuit including:
a first reversing circuit that reverses a first driving signal to output a first reverse driving signal;
a first signal level converting circuit that converts the first driving signal to a signal having a predetermined level to output;
a second signal level converting circuit that converts the first reverse driving signal to a signal having a predetermined level to output;
a first differential circuit that outputs a signal having a first polarity corresponding to a difference between the signal output from the first signal level converting circuit and the signal output from the second signal level converting circuit;
a second differential circuit that outputs a signal having a second polarity opposite to the first polarity and corresponding to a difference between the signal output from the second signal level converting circuit and the signal output from the first signal level converting circuit;
a first output signal generating circuit that generates a first output signal based on the signal having the first polarity output from the first differential circuit; and
a second output signal generating circuit that generates a second output signal based on the signal having the second polarity output from the second differential circuit; and
at least one second output circuit that outputs a single forward or reverse signal, the second output circuit including:
a second reversing circuit that reverses a second driving signal to output a second reverse driving signal;
a third signal level converting circuit that converts the second driving signal to a signal having a predetermined level to output;
a fourth signal level converting circuit that converts the second reverse driving signal to a signal having a predetermined level to output;
a third differential circuit that outputs a signal having a first polarity corresponding to a difference between the signal output from the third signal level converting circuit and the signal output from the fourth signal level converting circuit;
a loading circuit connected to an output terminal of each of the third and the fourth signal level converting circuits to have a load capacitance approximately equal to a load capacitance of the third differential circuit, and
a third output signal generating circuit that generates the forward or reverse signal based on the signal having the first polarity output from the third differential circuit,
wherein each of the first to the fourth signal level converting circuits includes
a first MOS transistor of a first type whose gate receives the first driving signal, the first reverse driving signal, the second driving signal, or the second reverse driving signal and whose drain outputs a signal;
a second MOS transistor of a second type whose gate receives a third driving signal and whose drain outputs a signal; and
a negative feedback circuit that negatively feeds back a signal obtained by synthesizing the signals output from the drains of the first and the second MOS transistors to the gate of the second MOS transistor to generate the third driving signal so as to control an operating point of the second MOS transistor.

15. An output circuit group, comprising:
at least one first output circuit that outputs a pair of differential signals, the first output circuit including:
a first reversing circuit that reverses a first driving signal to output a first reverse driving signal;
a first signal level converting circuit that converts the first driving signal to a signal having a predetermined level to output;
a second signal level converting circuit that converts the first reverse driving signal to a signal having a predetermined level to output;
a first differential circuit that outputs a signal having a first polarity corresponding to a difference between the signal output from the first signal level converting circuit and the signal output from the second signal level converting circuit;
a second differential circuit that outputs a signal having a second polarity opposite to the first polarity and corresponding to a difference between the signal output from the second signal level converting circuit and the signal output from the first signal level converting circuit;
a first output signal generating circuit that generates a first output signal based on the signal having the first polarity output from the first differential circuit, and a second output signal generating circuit that generates a second output signal based on the signal having the second polarity output from the second differential circuit; and
at least one second output circuit that outputs a single forward or reverse signal, the second output circuit including:
a second reversing circuit that reverses a second driving signal to output a second reverse driving signal;
a third signal level converting circuit that converts the second driving signal to a signal having a predetermined level to output;
a fourth signal level converting circuit that converts the second reverse driving signal to a signal having a predetermined level to output;
a third differential circuit that outputs a signal having a first polarity corresponding to a difference between the signal output from the third signal level converting circuit and the signal output from the fourth signal level converting circuit;
a loading circuit connected to an output terminal of each of the third and the fourth signal level converting circuits to have a load capacitance approximately equal to a load capacitance of the third differential circuit; and
a third output signal generating circuit that generates the forward or reverse signal based on the signal having the first polarity output from the third differential circuit,
wherein each of the first to the fourth signal level converting circuits includes:
a first MOS transistor whose gate receives the first driving signal, the first reverse driving signal, the second driving signal, or the second reverse driving signal and whose drain outputs a signal;
a second MOS transistor whose gate receives a third driving signal and whose source outputs a signal; and
a negative feedback circuit that reverses a signal obtained by synthesizing the signal output from the drain of the first MOS transistor and the signal output from the source of the second MOS transistor to negatively feeds back to the gate of the second MOS transistor to generate the third driving signal to control an operating point of the second MOS transistor.

16. The output circuit group according to claim 14, wherein a phase difference between the first and the third driving signals is approximately equal to a phase difference between the differential signals output from the first output circuit and the forward or reverse signal output from the second output circuit.

17. The output circuit group according to claim 14, wherein the loading circuit is a dummy differential circuit having a structure approximately equal to a structure of the third differential circuit.

18. The output circuit group according to claim 14, wherein the loading circuit includes a first loading element having a load capacitance approximately equal to an input load capacitance of a first input terminal of the third differential circuit and a second loading element having a load capacitance approximately equal to an input load capacitance of a second input terminal of the third differential circuit.

19. A semiconductor integrated circuit, comprising:
a chip having a plurality of circuit regions formed thereon, each region having separate power supplies; and
the output circuit group according to claim 14, the output circuit group being formed in one of the circuit regions.

20. The semiconductor integrated circuit according to claim 19, wherein the one of the circuit regions having the output circuit group formed therein includes a plurality of power supply voltage regions formed in parallel in a side direction of the chip, and each of the first and the second output circuits included in the output circuit group is formed so as to straddle the power supply voltage regions.
